(19) United States
(12) Patent Application Publication
(10) Pub. No.: US 2015/0280129 A1
(43) Pub. Date: Oct. 1, 2015

(54) STRETCHABLE DEVICE, METHOD OF MANUFACTURING THE SAME, AND ELECTRONIC APPARATUS INCLUDING STRETCHABLE DEVICE

(71) Applicants: SAMSUNG ELECTRONICS CO., LTD., Suwon-si (KR); The Board of Trustees of the Leland Stanford Junior University, Palo Alto, CA (US)

(72) Inventors: Tae-Ho KIM, Suwon-si (KR); Alex CHORTOS, Palo Alto, CA (US); Zhenan BAO, Stanford, CA (US); Sungwoo HWANG, Seoul (KR)

(73) Assignees: SAMSUNG ELECTRONICS CO., LTD., Suwon-si (KR); The Board of Trustees of the Leland Stanford Junior University, Palo Alto, CA (US)

(21) Appl. No.: 14/589,396

(22) Filed: Jan. 5, 2015

(30) Foreign Application Priority Data
Mar. 27, 2014 (KR) 10-2014-0036127

(51) Int. Cl. H01L 51/00; H01L 51/10; H01L 51/05; H01L 51/56

(52) U.S. Cl. CPC H01L 51/0004; H01L 51/56; H01L 51/105; H01L 51/0097; H01L 51/0508

(57) ABSTRACT

Provided are stretchable devices, methods of manufacturing the same, and electronic apparatuses including the stretchable devices. A stretchable device may include first and second material layers, each including an elastomeric polymer, and an organic layer that is disposed between the first and second material layers. The organic layer may include an organic semiconductor. As least one electrode element may be embedded in at least one of the first and second material layers. The at least one electrode element may be electrically connected to the organic layer. The stretchable device may be stretchable in a direction parallel to the organic layer. The stretchable device may be a transistor, and may further include a gate electrode.

### RELATED APPLICATION

This application claims priority from Korean Patent Application No. 10-2014-0036127, filed on Mar. 27, 2014, in the Korean Intellectual Property Office, the disclosure of which is incorporated herein in its entirety by reference.

### BACKGROUND

1. Field

Apparatuses and methods consistent with exemplary embodiments relate to stretchable devices, methods of manufacturing the same, and electronic apparatuses including the stretchable devices.

2. Description of the Related Art

Recently, an interest in flexible electronic apparatuses has increased. Flexible electronics are electronic circuits/apparatuses that may be bent or folded and are achieved by mounting an electronic device on a flexible substrate made of a material such as plastic. In particular, flexible electronics may be a next-generation technology in the field of display devices.

A desire has emerged for an electronic apparatus that is stretchable (extensible), in addition to being flexible. A flexible electronic apparatus may be bent while maintaining its length whereas a stretchable electronic apparatus may be bent and also allows its length to be increased. Stretchable electronics are expected to be useful in any of a variety of new applications. Examples of potential applications for stretchable electronics include electronic skins and skin sensors for moving robotic apparatuses, wearable electronic apparatuses, and bio-integrated devices. Also, stretchable devices may be useful in any of various other applications including in display devices or sensor arrays.

### SUMMARY

One or more exemplary embodiments may provide stretchable devices having characteristics such as a high tensile strain, excellent performance even after repeated stretching operations, and relatively simple structures that are easily manufactured.

One or more exemplary embodiments may provide methods of manufacturing stretchable devices.

One or more exemplary embodiments may provide apparatuses including stretchable devices.

Additional exemplary aspects and advantages will be set forth in part in the description which follows and, in part, will be apparent from the description, or may be learned by practice of the presented embodiments.

According to an aspect of an exemplary embodiment, a stretchable device includes: a first material layer that includes an elastomeric polymer and is stretchable; a second material layer that faces the first material layer, includes an elastomeric polymer, and is stretchable; an organic layer that is disposed between the first and second material layers, and includes an organic semiconductor; and at least one electrode element that is embedded in at least one of the first and second material layers and contacts the organic layer, wherein the stretchable device is stretchable in a direction parallel to the organic layer.

Each of the elastomeric polymer of the first material layer and the elastomeric polymer of the second material layer may have a Poisson's ratio of 0.4 or more.

At least one of the elastomeric polymer of the first material layer and the elastomeric polymer of the second material layer may include at least one material selected from a group consisting of polyurethane, polyurethane acrylate, acrylate polymer, acrylate terpolymer, and silicone-based polymer.

The silicone-based polymer may include at least one material selected from a group consisting of polydimethylsiloxane, polyphenylmethylsiloxane, and hexamethyldisiloxane.

The organic semiconductor may include an organic material having a conjugated structure.

The organic semiconductor may include at least one material selected from a group consisting of poly(3-hexylthiophene), TIPS-pentacene, pentacene, cyano-polyphenylene vinylene, polyacetylene, polyaniline, poly(phenylene ethynylene), poly(phenylene sulfide), poly(phenylene vinylene), polypyridine, polypyrrole, polythiophene, and polyfluorene-based polymer.

The at least one electrode element may have a network structure.

The at least one electrode element may include at least one material selected from a group consisting of carbon nanotubes (CNTs), metal nanowires, and graphene.

The at least one electrode element may include first and second electrodes that are embedded in one of the first and second material layers, and the first and second electrodes may be separate from each other.

The at least one electrode element may include a first electrode that is embedded in the first material layer, and a second electrode that is embedded in the second material layer.

The stretchable device may be a transistor, wherein the at least one electrode element includes a source electrode and a drain electrode that are embedded in one of the first and second material layers, and wherein the stretchable device further includes a gate electrode configured to apply an electric field to the organic layer.

The gate electrode may include at least one material selected from a group consisting of a liquid metal, CNTs, metal nanowires, and graphene.

The stretchable device may further include an elastic protective layer that covers the gate electrode.

The stretchable device may be a photovoltaic device, including a first electrode that is embedded in a side of the first material layer adjacent to the organic layer and a second electrode that is embedded in a side of the second material layer adjacent to the organic layer, and wherein at least one of the first and second electrodes corresponds to the at least one electrode element.

The stretchable device may be a light-emitting device, including a first electrode that is embedded in a side of the first material layer adjacent to the organic layer and a second electrode that is embedded in a side of the second material layer adjacent to the organic layer, wherein at least one of the first and second electrodes corresponds to the at least one electrode element.

The stretchable device may be under a strain of 10% or more.

Semiconductor characteristics of the stretchable device under no strain may be substantially the same as semiconductor characteristics of the stretchable device under a strain of 150% or more, due to nano-cracks in the organic layer.

The stretchable device may be under a strain of 200% or more.

The stretchable device may be under a strain of 250% or more.

According to an aspect of another exemplary embodiment, a stretchable transistor includes: a first elastomeric polymer layer that has a Poisson's ratio of 0.4 or more; a second elastomeric polymer layer that faces the first elastomeric polymer layer and has a Poisson's ratio of 0.4 or more; an organic semiconductor layer that is disposed between the first and second elastomeric polymer layers; a source electrode and a drain electrode that are embedded in one of the first and second elastomeric polymer layers and are electrically connected to the organic semiconductor layer; and a gate electrode that is disposed on one of the first and second elastomeric polymer layers.

Each of the source electrode and the drain electrode may include a network (CNT) structure.

The gate electrode may include a liquid metal.

Each of the first and second elastomeric polymer layers may include at least one material selected from a group consisting of polyurethane, polyurethane acrylate, and polydimethylsiloxane.

The organic semiconductor layer may include at least one material selected from a group consisting of poly(3-hexylthiophene), TIPS-pentacene, pentacene, cyano-polyphenylene vinylene, polyacetylene, polyaniline, poly(phenylene ethynylene), poly(phenylene sulfide), poly(phenylene vinylene), polypyridine, polypyrrole, polythiophene, and polyfluorene-based polymer.

According to an aspect of another exemplary embodiment, a method of manufacturing a stretchable device includes: preparing a first material layer including a stretchable elastomeric polymer; forming an organic layer on the first material layer, the organic layer including an organic semiconductor; and forming a second material layer on the organic layer, the second material layer including a stretchable elastomeric polymer, wherein at least one of the first and second material layers is formed to include at least one electrode element that contacts the organic layer.

The preparing of the first material layer may include: forming the at least one electrode element on a substrate; forming a material layer on the substrate, wherein the at least one electrode element is embedded in the material layer; and separating the material layer, along with the at least one electrode element embedded therein, from the substrate.

Each of the elastomeric polymer of the first material layer and the elastomeric polymer of the second material layer may have a Poisson's ratio of 0.4 or more.

At least one of the elastomeric polymer of the first material layer and the elastomeric polymer of the second material layer may include at least one material selected from a group consisting of polyurethane, polyurethane acrylate, acrylate polymer, acrylate terpolymer, and silicone-based polymer, wherein the silicon-based polymer includes at least one selected from the group consisting of polydimethylsiloxane, polyphenylmethylsiloxane, and hexamethyldisiloxane.

The organic semiconductor may include at least one material selected from a group consisting of poly(3-hexylthiophene), TIPS-pentacene, pentacene, cyano-polyphenylene vinylene, polyacetylene, polyaniline, poly(phenylene ethynylene), poly(phenylene sulfide), poly(phenylene vinylene), polypyridine, polypyrrole, polythiophene, and polyfluorene-based polymer.

The organic layer may be formed by using transfer printing.

The at least one electrode element may include at least one material selected from a group consisting of CNTs, metal nanowires, and graphene.

The at least one electrode element may include first and second electrodes that are spaced apart from each other.

The stretchable device may be a transistor, and the at least one electrode element may include a source electrode and a drain electrode, and the method may further include forming a gate electrode that corresponds to the organic layer.

The gate electrode may include at least one material selected from a group consisting of a liquid metal, CNTs, metal nanowires, and graphene.

The method may further include forming an elastic protective layer that covers the gate electrode.

The stretchable device may be a photovoltaic device, a light-emitting device, or a sensor.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

These and/or other exemplary aspects and advantages will become apparent and more readily appreciated from the following description of exemplary embodiments, taken in conjunction with the accompanying drawings in which:

FIG. 1 is a cross-sectional view illustrating a stretchable device according to an exemplary embodiment;

FIG. 2 is a plan view illustrating an example of a planar structure of the stretchable device of FIG. 1;

FIG. 3 is a cross-sectional view illustrating a stretchable device according to another exemplary embodiment;

FIG. 4 is a cross-sectional view illustrating a stretchable device according to another exemplary embodiment;

FIG. 5 is a cross-sectional view illustrating a stretchable device according to another exemplary embodiment;

FIG. 6 is a cross-sectional view illustrating a stretchable device according to another exemplary embodiment;

FIG. 7 is a cross-sectional view illustrating a stretchable device according to another exemplary embodiment;

FIG. 8 is a cross-sectional view illustrating a stretchable device according to another exemplary embodiment;

FIG. 9 is a cross-sectional view illustrating a stretchable device according to another exemplary embodiment;

FIG. 10 is a cross-sectional view illustrating a stretchable device according to another exemplary embodiment;

FIGS. 11A through 11G are cross-sectional views for explaining a method of manufacturing a stretchable device, according to an exemplary embodiment;

FIGS. 12A through 12E are cross-sectional views for explaining a method of forming an organic semiconductor layer by using transfer printing, according to an exemplary embodiment;

FIGS. 13A through 13G are cross-sectional views for explaining a method of manufacturing a stretchable device, according to another exemplary embodiment;

FIGS. 14A through 14C are cross-sectional views for explaining a method of manufacturing a stretchable device, according to another exemplary embodiment;

FIG. 15 shows images showing a manufacturing procedure of a stretchable device, according to an exemplary embodiment;

FIG. 16 shows images showing an unstretched state (undeformed state) and a 150%-strained state (150%-deformed state) of a stretchable device, according to an exemplary embodiment;

FIG. 17 is a graph illustrating a transfer curve of a device (transistor) that is tensile-strained as shown in FIG. 16B;

FIG. 18 shows optical microscope images illustrating a variation in morphology of an organic semiconductor layer (P3HT layer) depending on a degree of strain of a device structure (multi-layer structure), according to a comparative example and an exemplary embodiment, where P3HT is poly(3-hexylthiophene);

FIG. 19 is an atomic force microscope (AFM) image illustrating a state of a P3HT layer after a PU/P3HT structure according to a comparative example is deformed at a strain of 50%, where PU is polyurethane;

FIG. 20 is a graph illustrating a relationship between ON/OFF current and deformation of a stretchable device (transistor), according to an exemplary embodiment;

FIG. 21 is a graph illustrating a relationship between a gate factor (GF) and deformation of a stretchable device (transistor), according to an exemplary embodiment;

FIG. 22 is a graph illustrating a change in ON-current of a stretchable device (transistor) depending on a deformation cycle when the stretchable device is deformed (strained) in a parallel direction, according to an exemplary embodiment;

FIG. 23 is a graph illustrating a change in ON-current of a stretchable device (transistor) depending on a deformation cycle when the stretchable device is deformed (strained) in a perpendicular direction, according to an exemplary embodiment;

FIG. 24 is a graph illustrating a relationship between transfer characteristics and the number of stretching operations of a stretchable device, according to an exemplary embodiment;

FIG. 25 is a graph illustrating a variation of transfer characteristics depending on the passage of time after 100 stretching operations of a stretchable device, according to an exemplary embodiment;

FIG. 26 is a graph illustrating light absorption characteristics of an organic semiconductor layer (P3HT layer) in a device structure (multi-layer structure), according to a comparative example and an exemplary embodiment;

FIGS. 27 and 28 are graphs illustrating absorption spectra of a device structure (multi-layer structure) with respect to polarized incident light when the device structure is deformed (strained) in a perpendicular direction and a parallel direction, according to an exemplary embodiment;

FIG. 29 is a graph illustrating a relationship between properties and deformation of a PU layer that may be used in a stretchable device, according to an exemplary embodiment;

FIG. 30 is a graph illustrating a relationship between properties and a deformation cycle number of a PU layer that may be used in a stretchable device, according to an exemplary embodiment; and

FIG. 31 is a graph illustrating stress-strain characteristics of a PU layer that may be used in a stretchable device, according to an exemplary embodiment.

### DETAILED DESCRIPTION

Various exemplary embodiments will now be described more fully with reference to the accompanying drawings.

It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present. As used herein the term “and/or” includes any and all combinations of one or more of the associated listed items. Expressions such as “at least one of,” when preceding a list of elements, modify the entire list of elements and do not modify the individual elements of the list.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper”, and the like, may be used herein for ease of description to describe the relationship of one element or feature to another element or feature as illustrated in the figures. It will be understood that spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and, “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized examples (and intermediate structures) of exemplary embodiments. As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, stretchable devices, methods of manufacturing stretchable devices, and electronic apparatuses including stretchable devices according to exemplary embodiments will be described more fully with reference to the accompanying drawings. In the drawings, widths and thickness of layers or regions are exaggerated for clarity. Like reference numerals denote like elements throughout.

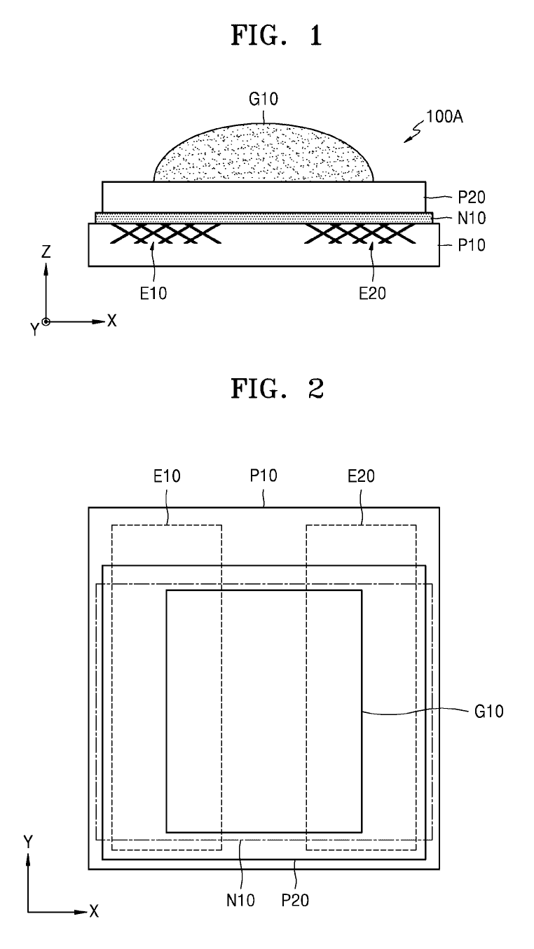

FIG. 1 is a cross-sectional view illustrating a stretchable device 100A according to an exemplary embodiment.

Referring to FIG. 1, the stretchable device 100A may include a first material layer P10. The first material layer P10 may include an elastomeric polymer and may be stretchable. The elastomeric polymer may be elastomeric rubber. The stretchable device 100A may include a second material layer P20 disposed over the first material layer P10 and facing the first material layer P10. The second material layer P20 may be formed of a material which is substantially the same as or similar to that of the first material layer P10. That is, the second material layer P20 may include an elastomeric polymer (e.g., elastomeric rubber) and may be stretchable. The elastomeric polymer of the second material layer P20 may be the same as or different from the elastomeric polymer of the first material layer P10.

The stretchable device 100A may include an organic semiconductor layer N10 that is disposed between the first and second material layers P10 and P20. The organic semiconductor layer N10 may include an organic material having a conjugated structure. The organic material may have semiconductor characteristics. The organic semiconductor layer N10 may contact the first and second material layers P10 and P20. In a device region, 70% or more of a bottom surface of the organic semiconductor layer N10 may be covered by the first material layer P10 and 70% or more of a top surface of the organic semiconductor layer N10 may be covered by the second material layer P20. For example, the bottom surface of the organic semiconductor layer N10 may be completely covered by the first material layer P10, and 80% or more of the top surface of the organic semiconductor layer N10 may be covered by the second material layer P20. Alternatively, the top surface of the organic semiconductor layer N10 may be completely covered by the second material layer P20.

At least one electrode element may be embedded in at least one of the first and second material layers P10 and P20. In FIG. 1, first and second electrodes E10 and E20 are separately embedded in the first material layer P10. The first and second electrodes E10 and E20 may be electrically connected to the organic semiconductor layer N10. The first and second electrodes E10 and E20 may be in contact with the organic semiconductor layer N10. At least a part of each of the first and second electrodes E10 and E20 may be embedded in a surface of the first material layer P10 and may be in direct contact with the organic semiconductor layer N10.

The stretchable device 100A of FIG. 1 may be a transistor. In this case, the organic semiconductor layer N10 may be a channel layer and the first and second electrodes E10 and E20 may be a source electrode and a drain electrode, respectively. Also, the stretchable device 100A may further include a gate electrode G10. The gate electrode G10 may be an element configured to be used to apply an electric field to the organic semiconductor layer N10. The gate electrode G10 may be formed of a stretchable conductive material, for example, a liquid metal. The gate electrode G10 may be disposed on either one of the first and second material layers P10 and P20, for example, on the second material layer P20. In this case, the second material layer P20 that is disposed between the gate electrode G10 and the organic semiconductor layer N10 (that is, the channel layer) may function as a “gate insulating layer”. When the second material layer P20 is used as a gate insulating layer, a thickness of the second material layer P20 may be equal to or less than about 10 μm; equal to or less than about 3 μm; or equal to or less than about 1 μm. For example, when the second material layer P20 is used as a gate insulating layer, a thickness of the second material layer P20 may range from about 10 nm to about 10 μm. The first material layer P10 may be a substrate. When the stretchable device 100A is a transistor, the transistor may be a field-effect transistor (FET).

Materials of the stretchable device 100A of FIG. 1 and characteristics of the materials will now be explained in more detail.

Each of the elastomeric polymer of the first material layer P10 and the elastomeric polymer of the second material layer P20 may be a material having a Poisson's ratio of 0.4 or more. The term “Poisson's ratio” refers to a ratio between a horizontal strain and a vertical strain when normal stress (perpendicular stress) is applied to a material. When a polymer has a Poisson's ratio of 0.4 or more, it means that the polymer is easily stretchable like rubber (that is, elastomeric rubber). At least one of the elastomeric polymer of the first material layer P10 and the elastomeric polymer of the second material layer P20 may include at least one material selected from a group consisting of polyurethane, polyurethane acrylate, acrylate polymer, acrylate terpolymer, and silicone-based polymer. The silicone-based polymer may include at least one material selected from a group consisting of polydimethylsiloxane, polyphenylmethylsiloxane, and hexamethyldisiloxane. Polyurethane may be denoted by “PU”, polyurethane acrylate may be denoted by “PUA”, and polydimethylsiloxane may be denoted by “PDMS”. The above materials may each have a Poisson's ratio of 0.4 or more. For example, PU may have a Poisson's ratio of 0.5 and PDMS may have a Poisson's ratio of 0.48. Also, materials of the first and second material layers P10 and P20 may have viscoelasticity. The materials of the first and second material layers P10 and P20 above are exemplary, and other elastomeric polymers may be used.

The organic semiconductor layer N10 that is disposed between the first and second material layers P10 and P20 may include an organic material having semiconductor characteristics due to a conjugated structure. The organic material of the organic semiconductor layer N10 may be a high molecular weight organic material or a low molecular weight organic material. In detail, the organic semiconductor layer N10 may include at least one material selected from a group consisting of poly(3-hexylthiophene), TIPS-pentacene, pentacene, cyano-polyphenylene vinylene, polyacetylene, polyaniline, poly(phenylene ethynylene), poly(phenylene sulfide), poly(phenylene vinylene), polypyridine, polypyrrole, polythiophene, and polyfluorene-based polymer. The polyfluorene-based polymer may include, for example, polyfluorene, poly(fluorene vinylene), or poly(fluorenylene ethynylene). Poly(3-hexylthiophene) may be denoted by “P3HT”, cyano-polyphenylene vinylene may be denoted by “CN-PPV”, polyaniline may be denoted by “PANi”, poly(phenylene ethynylene) may be denoted by “PPE”, poly(phenylene vinylene) may be denoted by “PPV”, polypyrrole may be denoted by “PPy”, polythiophene may be denoted by “PT”, polyfluorene may be denoted by “PFO”, poly(fluorene vinylene) may be denoted by “PFV”, and poly(fluorenylene ethynylene) may be denoted by “PFE”. Poly(3-hexylthiophene), cyano-polyphenylene vinylene, polyacetylene, polyaniline, poly(phenylene ethynylene), poly(phenylene sulfide), poly(phenylene vinylene), polypyridine, polypyrrole, polythiophene, and polyfluorene-based polymer may be high molecular weight organic materials, and the TIPS-pentacene and pentacene may be low molecular weight organic materials. The organic semiconductor layer N10 may include a copolymer including at least one of the above materials. The materials of the organic semiconductor layer N10 above are exemplary, and as long as an organic material has semiconductor characteristics due to a conjugated structure, the organic material may be used in the organic semiconductor layer N10.

Each of the first and second electrodes E10 and E20 may have, for example, a network structure. Each of the first and second electrodes E10 and E20 may include at least one material selected from a group consisting of carbon nanotubes (CNTs), metal nanowires, and graphene. In detail, each of the first and second electrodes E10 and E20 may have a structure in which a plurality of CNTs, a plurality of metal nanowires, or a plurality of graphene flakes are networked. The first and second electrodes E10 and E20 constructed as described above may be embedded in the first material layer P10. In this case, even when the stretchable device 100A is stretched in a predetermined direction, the first and second electrodes E10 and E20 may flexibly deal with (or endure) the tensile deformation and may maintain their appropriate functions.

The gate electrode G10 may be formed of a stretchable conductive material, for example, a liquid metal. The liquid metal may include, for example, eutectic gallium-indium (EGaIn). However, the gate electrode G10 may be configured in any of various other ways. For example, the gate electrode G10 may include CNTs, metal nanowires, or graphene embedded in an elastomeric polymer layer. In this case, the gate electrode G10 may be configured similarly to the first and second electrodes E10 and E20.

In FIG. 1, the organic semiconductor layer N10 may be disposed between the first and second material layers P10 and P20 that are each formed of an elastomeric polymer (e.g., elastomeric rubber) and are each stretchable. In this case, even when a structure including the organic semiconductor layer N10 that is disposed between the first and second material layers P10 and P20 is stretched or deformed in a direction (e.g., an X-axis direction or a Y-axis direction) parallel to the organic semiconductor layer N10, properties (semiconductor characteristics) of the organic semiconductor layer N10 may be maintained. Although the organic semiconductor layer N10 itself may have insufficient stretchable characteristics, unlike elastomeric rubber, since the first and second material layers P10 and P20 formed of an elastomeric polymer are disposed respectively at both sides (the top and bottom) of the organic semiconductor layer N10 and adhered to the organic semiconductor layer N10, even when the stretchable device 100A is stretched, cracks may be prevented from occurring in the organic semiconductor layer N10 and connections between polymer chains may be maintained. Accordingly, even when the stretchable device 100A is stretched, properties (semiconductor characteristics) of the organic semiconductor layer N10 may be maintained, and thus the performance of the stretchable device 100A (transistor) may be maintained. In more detail, when the stretchable device 100A is tensile-deformed, stress may be uniformly distributed through the entire organic semiconductor layer N10 that is sandwiched between the first and second material layers P10 and P20. Thus, cracks on a micro-scale (that is, micro-cracks) may not occur or may rarely occur in the organic semiconductor layer N10, cracks on a nano-scale (that is, nano-cracks) may mainly occur in the organic semiconductor layer N10, and the connections between polymer chains may not be cut off due to the nano-cracks. Accordingly, even when the stretchable device 100A is greatly deformed (for example, is deformed at a strain of 200% or more), the stretchable device 100A may operate normally and may maintain excellent performance. An inorganic material tends to break or separate when stretched, whereas the organic semiconductor layer N10 of FIG. 1 may be stably stretched between the first and second material layers P10 and P20 that are each formed of an elastomeric polymer. Since each of the first and second electrodes E10 and E20 and the gate electrode G10 are made of materials which are flexible when tensile deformation is applied thereto, the electrodes E10, E20 and G10 may be advantageously applied to the stretchable device 100A. Accordingly, in FIG. 1, the stretchable device 100A may have excellent performance even while under a high tensile strain. In the current embodiment, when the organic semiconductor layer N10 is deformed, since micro-cracks may be prevented from occurring and only nano-cracks may occur, the stretchable device 100A may be referred to as a “stretchable device using nano-cracks (fine cracks)”.

FIG. 2 is a plan view illustrating an example of a planar structure of the stretchable device 100A of FIG. 1.

Referring to FIG. 2, each of the first and second electrodes E10 and E20 may be embedded in the first material layer P10. Each of the first and second electrodes E10 and E20 may extend in a predetermined direction, for example, a Y-axis direction, as shown. The organic semiconductor layer N10 may be disposed on the first material layer P10, and may be in contact with the first and second electrodes E10 and E20. The second material layer P20 may be disposed on the organic semiconductor layer N10, and the gate electrode G10 may be disposed on the second material layer P20. One end portion of each of the first and second electrodes E10 and E20 may be exposed and not covered by the organic semiconductor layer N10 and the second material layer P20. The exposed end portions of the first and second electrodes E10 and E20 may be contact regions that are connected to external terminals. However, the planar structure of FIG. 2 is exemplary and may be modified in any of various other ways.

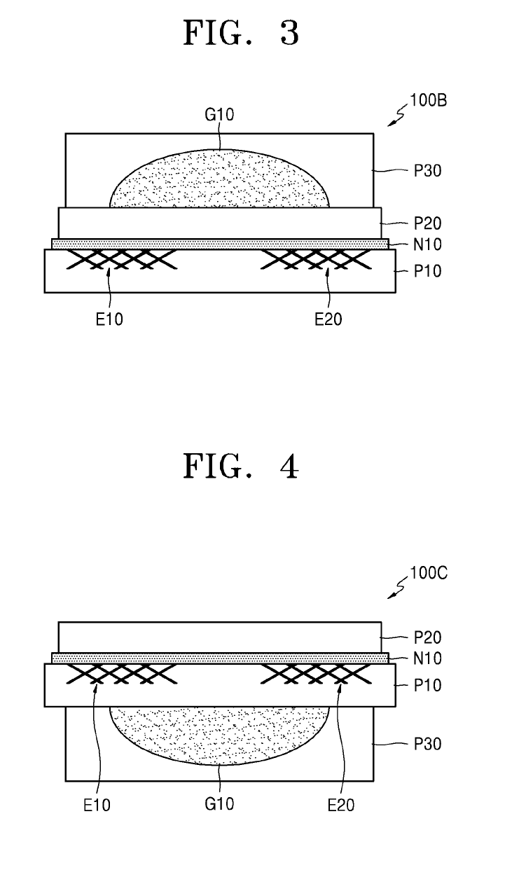

Alternatively, the stretchable device 100A may further include an elastic protective layer that covers the gate electrode G10 of FIG. 1, as shown in FIG. 3.

FIG. 3 is a cross-sectional view illustrating a stretchable device 100B according to another exemplary embodiment. Referring to FIG. 3, in addition to the features described above with respect to FIG. 1, the stretchable device 100B may further include an elastic protective layer P30 that is disposed on the second material layer P20 and over the gate electrode G10 to cover the gate electrode G10. The elastic protective layer P30 may be adhered to the second material layer P20 around the gate electrode G10. The elastic protective layer P30 may be formed of a material which is substantially the same as or similar to that of the first and second material layers P10 and P20. In other words, the elastic protective layer P30 may include an elastomeric polymer (e.g., elastomeric rubber), and may be stretchable. The elastomeric polymer of the elastic protective layer P30 may be substantially the same as or similar to that of the first and second material layers P10 and P20. The gate electrode G10 may be surrounded and protected by the elastic protective layer P30 and the second material layer P20 that is disposed under the elastic protective layer P30.

Although the gate electrode G10 is shown as disposed on a top surface of the second material layer P20 in FIGS. 1 and 3, the gate electrode G10 may be disposed on a bottom surface of the first material layer P10, as shown in FIG. 4.

FIG. 4 is a cross-sectional view illustrating a stretchable device 100C according to another exemplary embodiment. Referring to FIG. 4, the stretchable device 100C may include the gate electrode G10 disposed on the bottom surface of the first material layer P10. The elastic protective layer P30 may be disposed on the bottom surface of the first material layer P10, thus covering the gate electrode G10. The structure of FIG. 4 may be similar to that obtained by disposing the gate electrode G10 and the elastic protective layer P30 of FIG. 3 under the first material layer P10. However, in the structure of FIG. 4, a thickness of the first material layer P10 may be relatively small. Since a distance between the organic semiconductor layer N10 and the gate electrode G10 decreases as a thickness of the first material layer P10 decreases, characteristics of the organic semiconductor layer N10 may be more easily controlled by the gate electrode G10.

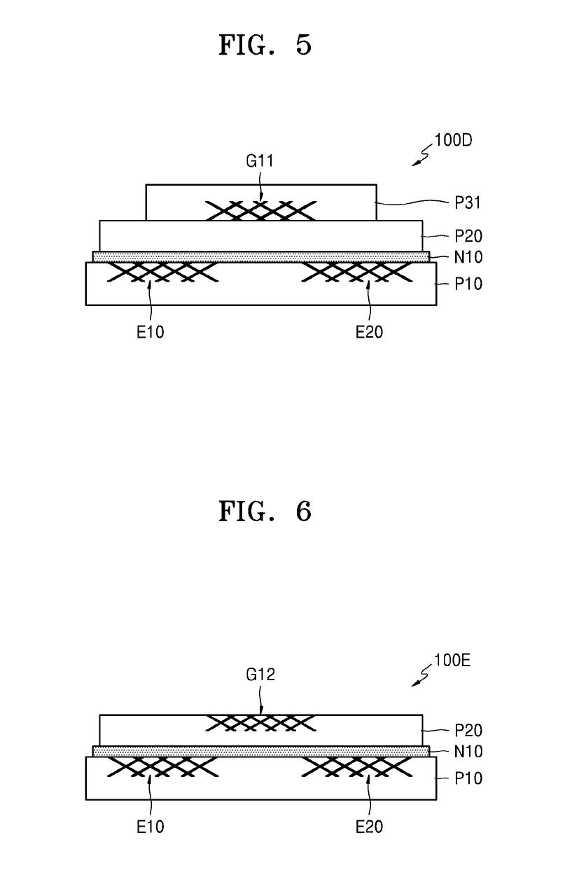

Although the gate electrode G10 is configured differently from the first and second electrodes E10 and E20 (that is, the source/drain electrodes) in FIGS. 1 through 4, the gate electrode G10 may be configured in substantially the same or a similar manner as the first and second electrodes E10 and E20, as shown in FIGS. 5 and 6.

FIG. 5 is a cross-sectional view illustrating a stretchable device 100D according to another exemplary embodiment. Referring to FIG. 5, the stretchable device 100D may include a third material layer P31, that is disposed on the second material layer P20, and a gate electrode G11 that is embedded in the third material layer P31. The third material layer P31 may be formed of substantially the same or a similar material as that of the first and second material layers P10 and P20. In other words, the third material layer P31 may include an elastomeric polymer (e.g., elastomeric rubber) and may be stretchable. The gate electrode G11 may be configured in substantially the same or a similar manner as the first and second electrodes E10 and E20. For example, the gate electrode G11 may have a structure in which a plurality of CNTs, a plurality of metal nanowires, or a plurality of graphene flakes are networked.

FIG. 6 is a cross-sectional view illustrating a stretchable device 100E according to another exemplary embodiment. Referring to FIG. 6, the stretchable device 100E may include a gate electrode G12 that is embedded in the second material layer P20. The gate electrode G12 may be configured in substantially the same or a similar manner as the first and second electrodes E10 and E20. The gate electrode G12 may be spaced apart from the organic semiconductor layer N10 without contacting the organic semiconductor layer N10. As such, when the gate electrode G12 is embedded in the second material layer P20, an interval between the gate electrode G12 and the organic semiconductor layer N10 may be reduced, and thus the gate electrode G12 may more easily control the organic semiconductor layer N10. Also, a total thickness of the stretchable device 100E may be reduced.

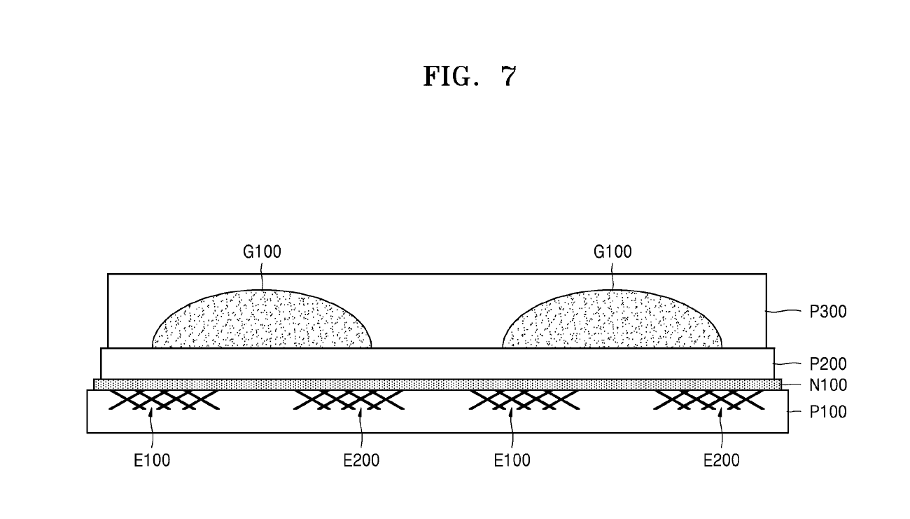

Alternatively, a plurality of devices may be disposed on a single first material layer, as shown in FIG. 7.

FIG. 7 is a cross-sectional view illustrating a stretchable device according to another exemplary embodiment. Referring to FIG. 7, a first material layer P100 and a second material layer P200 may be provided, and an organic semiconductor layer N100 may be disposed between the first and second material layers P100 and P200. The first and second material layers P100 and P200 may be formed of substantially the same or a similar material as that of the first and second material layers P10 and P20 of FIG. 1. The organic semiconductor layer N100 may be formed of substantially the same or a similar material as that of the organic semiconductor layer N10 of FIG. 1. A plurality of first electrodes E100 and a plurality of second electrodes E200 may be embedded in one of the first and second material layers P100 and P200, for example, in the first material layer P100, as shown. The plurality of first electrodes E100 may correspond to the first electrode E10 of FIG. 1, and the plurality of second electrodes E200 may correspond to the second electrode E20 of FIG. 1. The first electrodes E100 and the second electrodes E200 may be alternately arranged and may respectively correspond to source electrodes and drain electrodes. The first and second electrodes E100 and E200 may be electrically connected to the organic semiconductor layer N100. A plurality of gate electrodes G100 may be disposed on either one of the first and second material layers P100 and P200, for example, on the second material layer P200, as shown. Each of the gate electrodes G100 may be disposed in a location corresponding to a portion of the second material layer P200 between portions of the first material layer P100 in which a first electrode E100 and a second electrode E200 are embedded. An elastic protective layer P300 covering the plurality of gate electrodes G100 may be further provided. The structure of FIG. 7 may be similar to that obtained by continuously arranging two stretchable devices 100B of FIG. 3 in a horizontal direction (e.g., an X-axis direction of FIG. 1). In the structure of FIG. 7, the elastic protective layer P300 may be omitted. Also, the structure of FIG. 7 may be modified to correspond to any of the structures of FIGS. 4 through 6.

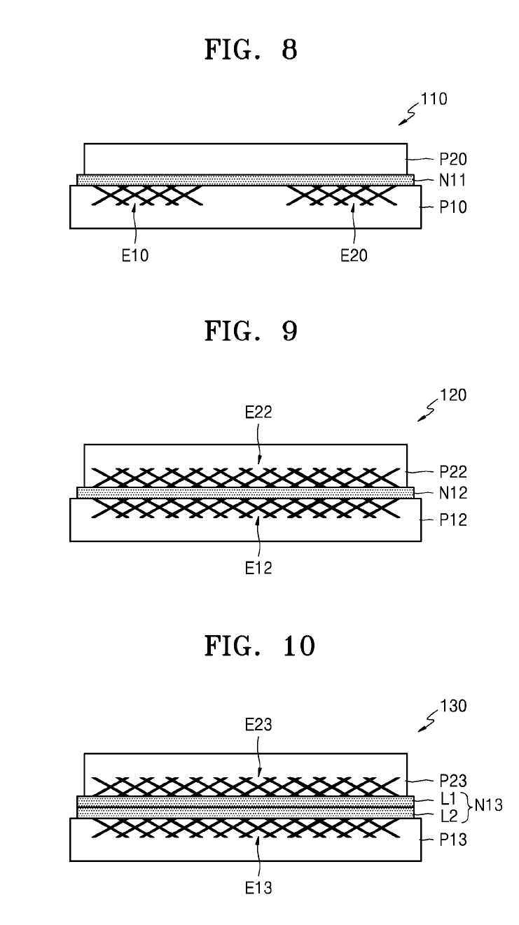

Although stretchable devices illustrated in FIGS. 1 through 7 each have a 3-terminal structure in which one device unit includes three electrodes (that is, source/drain/gate electrodes), a stretchable device may have a 2-terminal structure, as shown in FIG. 8.

FIG. 8 is a cross-sectional view illustrating a stretchable device 110 according to another exemplary embodiment of. A structure of the stretchable device 110 of FIG. 8 may correspond to that obtained by removing the gate electrode G10 from the stretchable device 100A of FIG. 1. The stretchable device 110 may be, for example, a sensor. The sensor may be an optical sensor. In this case, an organic semiconductor layer N11 may have an electrical conductivity that varies according to light. Since each of the first and second material layers P10 and P20 may be transparent or almost transparent, light may easily reach the organic semiconductor layer N11 through the first or second material layer P10 or P20. Since the electrical conductivity of the organic semiconductor layer N11 varies according to light, the intensity of current between the first and second electrodes E10 and E20 may vary.

The structure of the stretchable device 110 of FIG. 8 may be modified in any of various other ways. For example, the first electrode E10 may be embedded in the first material layer P10, the second electrode E20 may be embedded in the second material layer P20, or both the first and second electrodes E10 and E20 may be embedded in the second material layer P20. Also, the stretchable device 110 of FIG. 8 may be used as a sensor other than an optical sensor. According to the use of the stretchable device 110, a material of the organic semiconductor layer N11 may be determined.

The spirit and principle of the one or more exemplary embodiments described herein may be applied to a photovoltaic device and a light-emitting device. That is, a stretchable photovoltaic device (e.g., a solar cell) and a stretchable light-emitting device may be realized according to one or more exemplary embodiments, as shown in FIGS. 9 and 10. FIG. 9 illustrates an example of a stretchable photovoltaic device (e.g., a solar cell). FIG. 10 illustrates an example of a stretchable light-emitting device.

FIG. 9 is a cross-sectional view illustrating a stretchable device 120 according to another exemplary embodiment.

Referring to FIG. 9, the stretchable device 120 may include an organic layer N12 that is disposed between a first material layer P12 and a second material layer P22, wherein the organic layer N12 includes an organic semiconductor. The organic layer N12 may include a photoactive layer. A first electrode E12 may be embedded in the first material layer P12, and a second electrode E22 may be embedded in the second material layer P22. The first and second electrodes E12 and E22 may be electrically connected to the organic layer N12. For example, the first and second electrodes E12 and E22 may contact the organic layer N12. The organic layer N12 may include a photoactive material that is used in a typical organic solar cell. Also, the organic layer N12 may be formed of a mixture of a p-type organic material and an n-type organic material. For example, the organic layer N12 may include poly(3-hexylthiophene) (i.e., P3HT) as the p-type organic material and may include a fullerene derivative (e.g., a C60 derivative) as the n-type organic material. However, these materials of the organic layer N12 are merely exemplary and may be modified in any of various other ways. Also, the organic layer N12 may include the photoactive layer that is an organic layer and further include at least one additional organic layer. For example, the organic layer N12 may include the photoactive layer and a hole transport layer that is disposed between the photoactive layer and the second electrode E22. In this case, holes that are generated in the photoactive layer may be easily transported to the second electrode E22 via the hole transport layer. The stretchable device 120 of FIG. 9 may be configured in any of various other ways.

FIG. 10 is a cross-sectional view illustrating a stretchable device 130 according to another exemplary embodiment.

Referring to FIG. 10, the stretchable device 130 may include an organic layer N13 that is disposed between a first material layer P13 and a second material layer P23, wherein the organic layer N13 includes an organic semiconductor. The organic layer N13 may include an organic light-emitting layer L1. The organic light-emitting layer L1 may include an organic light-emitting material that is used in typical organic light-emitting devices. For example, the organic light-emitting layer L1 may include a polyfluorene-based polymer. The organic layer N13 may further include a hole injection layer L2 that is disposed between the organic light-emitting layer L1 and the first material layer P13. The hole injection layer L2 may be formed of a conductive polymer material. For example, the hole injection layer L2 may be formed of poly(3,4-ethylenedioxythiophene) (i.e., PEDOT). However, the materials of the organic light-emitting layer L1 and the hole injection layer L2 are not limited thereto and may be modified in any of various other ways. A first electrode E13 may be embedded in the first material layer P13, and a second electrode E23 may be embedded in the second material layer P23. The first electrode E13 may function as an anode, and the second electrode E23 may function as a cathode. The first electrode E13 may be electrically connected to a bottom surface of the organic layer N13 by contacting the bottom surface of the organic layer N13, and the second electrode E23 may be electrically connected to a top surface of the organic layer N13 by contacting the top surface of the organic layer N13.

In some cases, in the structure of FIG. 10, one of the first electrode E13 and the hole injection layer L2 may be omitted. For example, when the first electrode E13 is omitted, the hole injection layer L2 may also function as an electrode (anode). When the hole injection layer L2 is omitted, the first electrode E13 may contact a bottom surface of the organic light-emitting layer L1. The stretchable device 130 of FIG. 10 may be configured in any of various other ways.

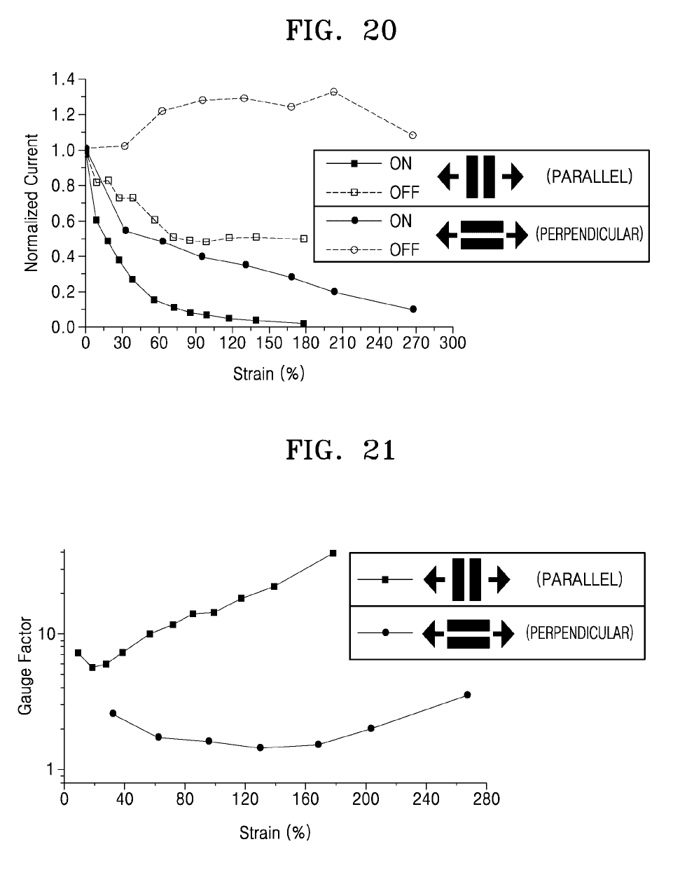

The stretchable device according to the one or more exemplary embodiments may have a strain of 10% or more. For example, the stretchable device according to one or more exemplary embodiments may be deformed to have a high strain of 200% or more. Based on data as will be described with reference to FIG. 20, even when the stretchable device is deformed to have a high strain of about 265%, the performance of the stretchable device may be maintained. As described above, since the organic layer N10, N11, N12, or N13 is disposed between the first material layer P10, P12, or P13 and the second material layer P20, P22, or P23, each including an elastomeric polymer (elastomeric rubber) and each being stretchable, even when the stretchable device 100A, 100B, 100C, 100D, 100E, 110, 120, or 130 is tensile-deformed, micro-cracks may not occur or hardly occur in the organic layer N10, N11, N12, or N13, nano-cracks (fine cracks having a width less than 1 μm) may uniformly occur, and connection between polymer chains may not be cut off, and thus characteristics (semiconductor characteristics) of the organic layer N10, N11, N12, or N13 may be maintained. Accordingly, even when the stretchable device 100A, 100B, 100C, 100D, 100E, 110, 120, or 130 is greatly deformed (for example, deformed to have a strain of 200% or more), the stretchable device 100A, 100B, 100C, 100D, 100E, 110, 120, or 130 may normally operate and may maintain excellent performance.

Alternatively, a predetermined organic adhesive layer may be further provided between the first material layer P10, P12, or P13 and the organic layer N10, N11, N12, or N13 and/or between the second material layer P20, P22, or P23 and the organic layer N10, N11, N12, or N13. An adhesive force between layers may be increased due to the organic adhesive layer. A thickness of the organic adhesive layer may be as small as possible. For example, the organic adhesive layer may have a thickness ranging from about 1 nm to about 50 nm. If the organic adhesive layer is disposed between the organic semiconductor layer N10 and the second material layer P20 of FIG. 1, the organic adhesive layer and the organic semiconductor layer N10 may be collectively considered as one “organic layer”. If necessary, a material for increasing an adhesive force, by changing surface (interfacial) characteristics, may be used, instead of the organic adhesive layer. In addition, at least one of the first material layer P10, P12, or P13 and the second material layer P20, P22, or P23 may include a polymer complex layer. That is, a variety of polymers may be mixed or multi-layered and then may be applied to the first material layer P10, P12, or P13 and/or the second material layer P20, P22, or P23.

Hereinafter, methods of manufacturing stretchable devices, according to exemplary embodiments, will be explained.

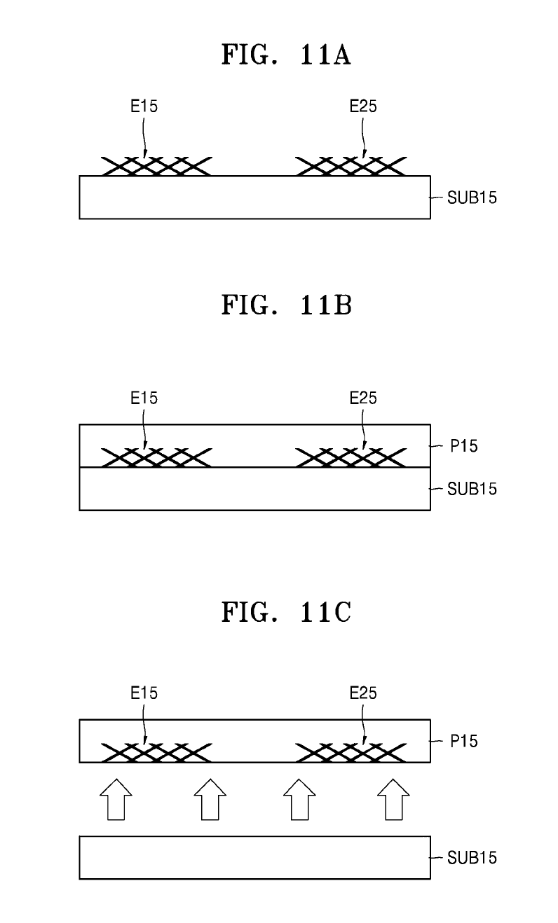

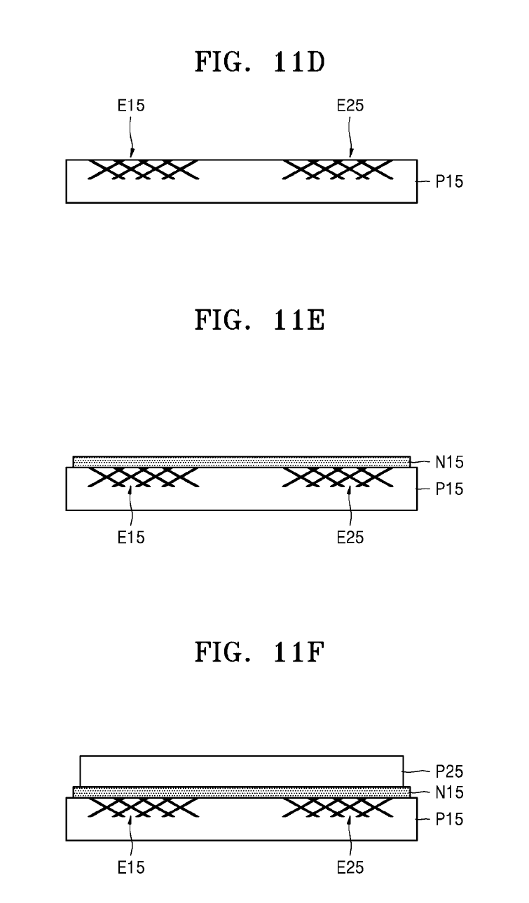

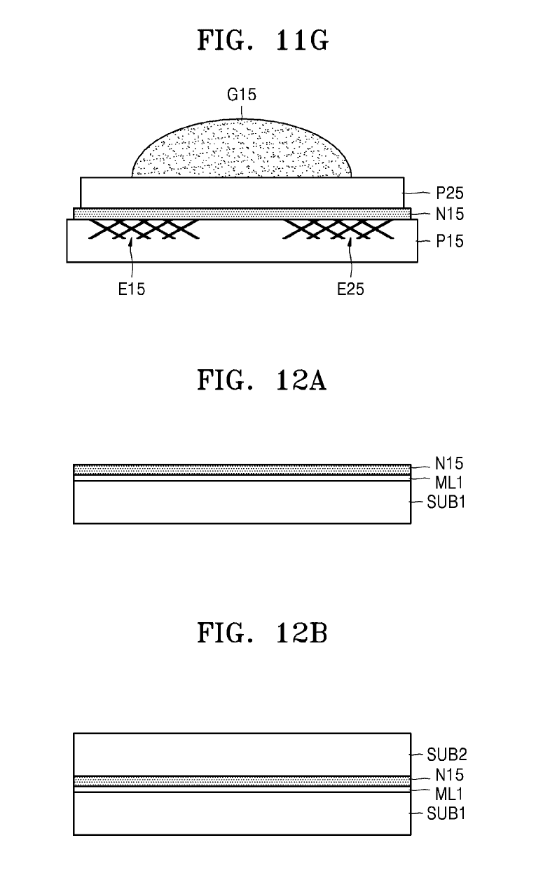

FIGS. 11A through 11G are cross-sectional views for explaining a method of manufacturing a stretchable device, according to an exemplary embodiment of the present invention.

Referring to FIG. 11A, at least one electrode element may be formed on a substrate SUB15. For example, first and second electrodes E15 and E25 that are spaced apart from each other may be formed on the substrate SUB15. The substrate SUB15 may be, for example, a silicon substrate, or may be any of various other substrates. Each of the first and second electrodes E15 and E25 may have a network structure. Also, each of the first and second electrodes E15 and E25 may include at least one material selected from a group consisting of CNTs, metal nanowires, and graphene. In detail, each of the first and second electrodes E15 and E25 may have a structure in which a plurality of CNTs, a plurality of metal nanowires, or a plurality of graphene flakes are networked. Each of the first and second electrodes E15 and E25 may be formed by using, for example, spray coating. In this case, a predetermined shadow mask (not shown) having one or more openings may be disposed on the substrate SUB15, and a solution, including a plurality of CNTs, may be coated by spraying on a portion of the substrate SUB15 that is exposed through the one or more openings of the predetermined shadow mask. In this case, the solution may be an alcohol-based solution such as ethanol or isopropanol (IPA). Next, when the shadow mask is removed, the first and second electrodes E15 and E25 each having a shape corresponding to an opening may remain on the substrate SUB15. Alternatively, the first and second electrodes E15 and E25 may be formed by forming a network CNT structure layer on an entire top surface of the substrate SUB15 and then patterning the network CNT structure layer. In this case, the network CNT structure layer may be patterned by using dry-etching in which oxygen (O2) plasma may be used. The method of forming the first and second electrodes E15 and E25 that is described in detail above is exemplary, and the first and second electrodes E15 and E25 may be formed by using any of various other methods.

Referring to FIG. 11B, a first material layer P15 may be formed on the substrate SUB15 covering the first and second electrodes E15 and E25. The first and second electrodes E15 and E25 may thereby be embedded in the first material layer P15. The first material layer P15 may include an elastomeric polymer and may be stretchable. For example, the first material layer P15 may be formed by preparing a polymer solution by mixing an organic solvent (e.g., a non-polar organic solvent) such as chlorobenzene with a predetermined elastomeric polymer, coating the polymer solution on the substrate SUB15 by using, for example, spin coating, and then drying a coated polymer layer. The drying may be performed at a temperature of, for example, about 120° C. or more. The elastomeric polymer of the first material layer P15 may have a Poisson's ratio of 0.4 or more. In detail, the elastomeric polymer of the first material layer P15 may include at least one material selected from a group consisting of polyurethane, polyurethane acrylate, acrylate polymer, acrylate terpolymer, and silicone-based polymer. The silicone-based polymer may include at least one material selected from a group consisting of, for example, polydimethylsiloxane, polyphenylmethylsiloxane, and hexamethyldisiloxane. Polyurethane may be denoted by “PU”, polyurethane acrylate may be denoted by “PUA”, and polydimethylsiloxane may be denoted by “PDMS”.

Referring to FIG. 11C, the first material layer P15 may be separated from the substrate SUB15. The first material layer P15 may be detached from the substrate SUB15 by using a physical method. Since the first and second electrodes E15 and E25 are embedded in the first material layer P15 and an adhesive force between the first and second electrodes E15 and E25 and the substrate SUB15 is not relatively strong, the first and second electrodes E15 and E25 may be easily separated from the substrate SUB15 along with the first material layer P15.

Next, the first material layer P15 may be overturned to make exposed portions of the first and second electrodes E15 and E25 face upward, as shown in FIG. 11D.

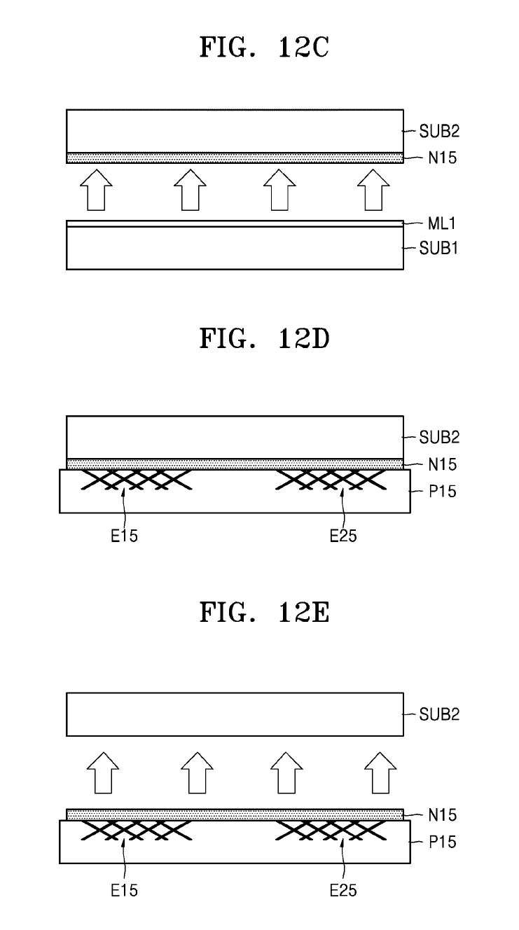

Referring to FIG. 11E, an organic semiconductor layer N15 may be formed on the first material layer P15. The organic semiconductor layer N15 may include an organic material having semiconductor characteristics due to a conjugated structure. For example, the organic semiconductor layer N15 may include at least one material selected from a group consisting of poly(3-hexylthiophene), TIPS-pentacene, pentacene, cyano-polyphenylene vinylene, polyacetylene, polyaniline, poly(phenylene ethynylene), poly(phenylene sulfide), poly(phenylene vinylene), polypyridine, polypyrrole, polythiophene, and polyfluorene-based polymer. The polyfluorene-based polymer may include, for example, polyfluorene, poly(fluorene vinylene), or poly(fluorenylene ethynylene). Poly(3-hexylthiophene) may be denoted by “P3HT”, cyano-polyphenylene vinylene may be denoted by “CN-PPV”, polyaniline may be denoted by “PANi”, poly(phenylene ethynylene) may be denoted by “PPE”, poly(phenylene vinylene) may be denoted by “PPV”, polypyrrole may be denoted by “PPy”, polythiophene may be denoted by “PT”, polyfluorene may be denoted by “PFO”, poly(fluorene vinylene) may be denoted by “PFV”, and poly(fluorenylene ethynylene) may be denoted by “PFE”. The organic semiconductor layer N15 may include a copolymer including at least one of the above materials. The organic semiconductor layer N15 may be formed by using, for example, transfer printing. A method of forming the organic semiconductor layer N15 by using transfer printing will be explained later in detail with reference to FIGS. 12A through 12E.

Referring to FIG. 11F, a second material layer P25 may be formed on the organic semiconductor layer N15. The second material layer P25 may be formed of substantially the same or a similar material as that of the first material layer P15. Accordingly, the second material layer P25 may include an elastomeric polymer and may be stretchable. The elastomeric polymer of the second material layer P25 may have a Poisson's ratio of 0.4 or more. In detail, the elastomeric polymer of the second material layer P25 may include at least one material selected from a group consisting of polyurethane, polyurethane acrylate, acrylate polymer, acrylate terpolymer, and silicone-based polymer. The silicone-based polymer may include at least one material selected from a group consisting of, for example, polydimethylsiloxane, polyphenylmethylsiloxane, and hexamethyldisiloxane. A method of forming the second material layer P25 may be similar to the method of forming the first material layer P15 described with reference to FIG. 11B. That is, the second material layer P25 may be formed by preparing a polymer solution by mixing a predetermined organic solvent (e.g., a non-polar organic solvent) with an elastomeric polymer, coating the polymer solution on the organic semiconductor layer N15 by using, for example, spin coating, and then drying a coated polymer layer. In this case, a solvent that does not damage the organic semiconductor layer N15 may be used as the organic solvent.

Referring to FIG. 11G, a gate electrode G15 may be formed on the second material layer P25. For example, the gate electrode G15 may be formed of a liquid metal. In this case, the gate electrode G15 may be formed by using, for example, nozzle printing. The liquid metal may include EGaIn. A material of the gate electrode G15 and a method of forming the gate electrode G15 may be modified in any of various other ways. For example, the gate electrode G15 may include CNTs, metal nanowires, or graphene flakes that are embedded in an elastomeric polymer layer. In this case, the gate electrode G15 may be configured in a manner similar to that of each of the first and second electrodes E15 and E25.

The structure of FIG. 11G may correspond to the stretchable device (stretchable transistor) 100A of FIG. 1. In FIG. 11G, an elastic protective layer may be further formed to cover the gate electrode G15. In this case, the structure of FIG. 3 may be obtained. Based on the method of FIGS. 11A through 11G, the stretchable device (stretchable transistor) of any of FIGS. 4 through 7 and the stretchable device (stretchable sensor) of FIG. 8 may be easily manufactured.

The method of forming the organic semiconductor layer N15 by using transfer printing described with reference to FIG. 11E will now be explained in more detail with reference to FIGS. 12A through 12E.

Referring to FIG. 12A, a molecular layer ML1 may be formed on a first substrate SUB1. The first substrate SUB1 may be, for example, a silicon substrate. The molecular layer ML1 may be a self-assembled monolayer (SAM). Next, the organic semiconductor layer N15 may be formed on the molecular layer ML1. The organic semiconductor layer N15 may be formed by using, for example, spin coating.

Referring to FIGS. 12B and 12C, the organic semiconductor layer N15 may be transferred from the first substrate USB1 to a second substrate SUB2 by pressing the organic semiconductor layer N15 onto the second substrate SUB2. In this case, the organic semiconductor layer N15 may be easily separated from the first substrate SUB1 due to the molecular layer ML1. The second substrate SUB2 may be a predetermined organic substrate. For example, the second substrate SUB2 may include PDMS.

Referring to FIGS. 12D and 12E, the organic semiconductor layer N15 of the second substrate SUB2 may be transferred to the first material layer P15 of FIG. 11D. Since an adhesive force between the organic semiconductor layer N15 and the first material layer P15 may be greater than an adhesive force between the second substrate SUB2 and the organic semiconductor layer N15, the organic semiconductor layer N15 may be separated from the second substrate SUB2 and may be attached to the first material layer P15. The second substrate SUB2, the second substrate SUB2 may be referred to as a stamp substrate.

The organic semiconductor layer N15 may be formed on the first material layer P15 by using transfer printing, as shown in FIG. 12E. If the organic semiconductor layer N15 is directly formed on the first material layer P15 by using spin coating, as in FIG. 11E, an organic material of the first material layer P15 may be damaged by a solvent that is used during the spin coating. Accordingly, in order to prevent damage to the first material layer P15 due to the solvent, transfer printing may be used. However, if a solvent that does not damage the first material layer P15 is used, the organic semiconductor layer N15 may be directly formed on the first material layer P15 by using spin coating.

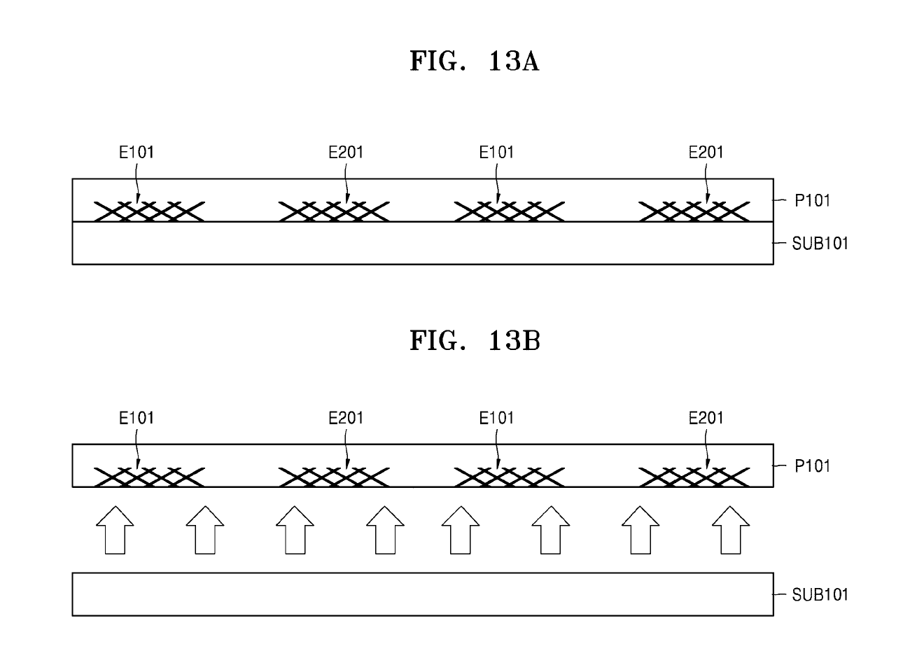

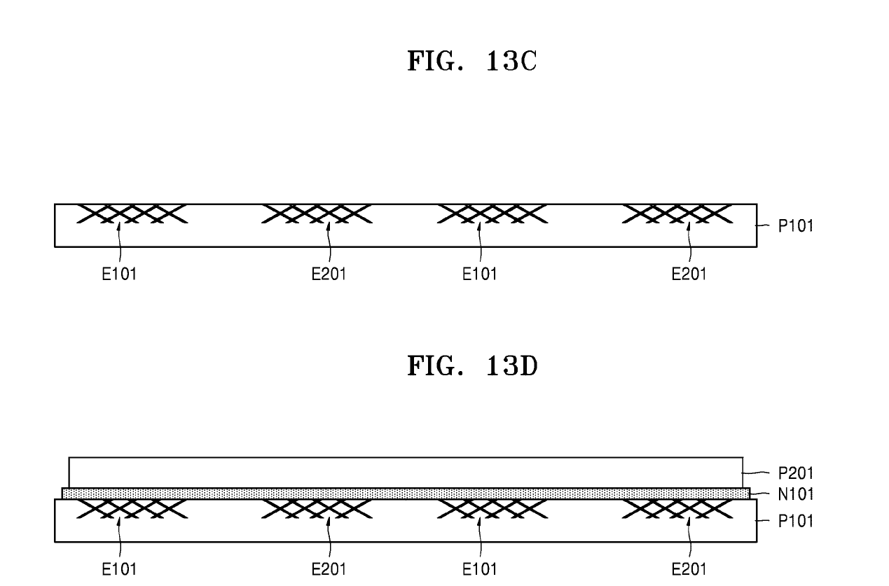

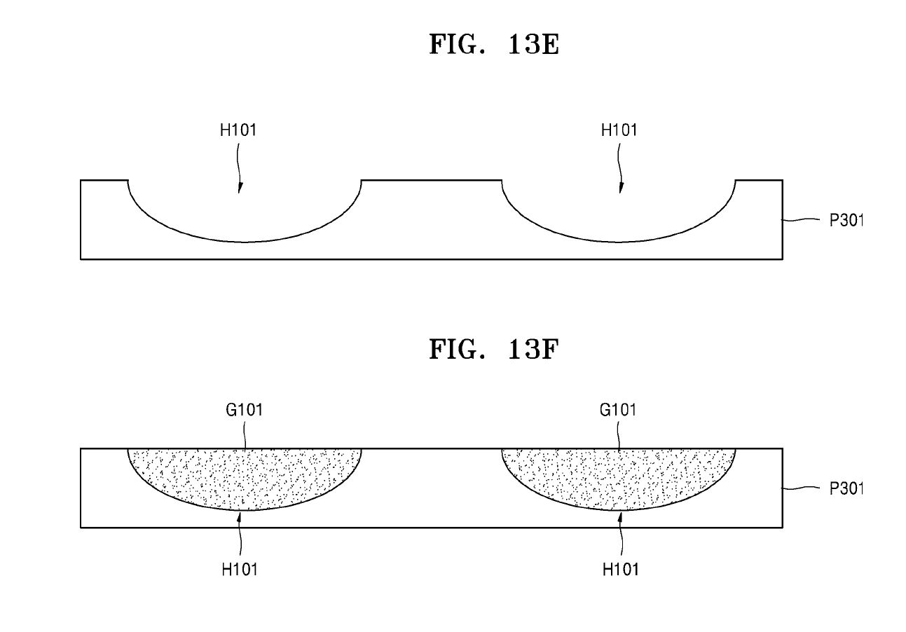

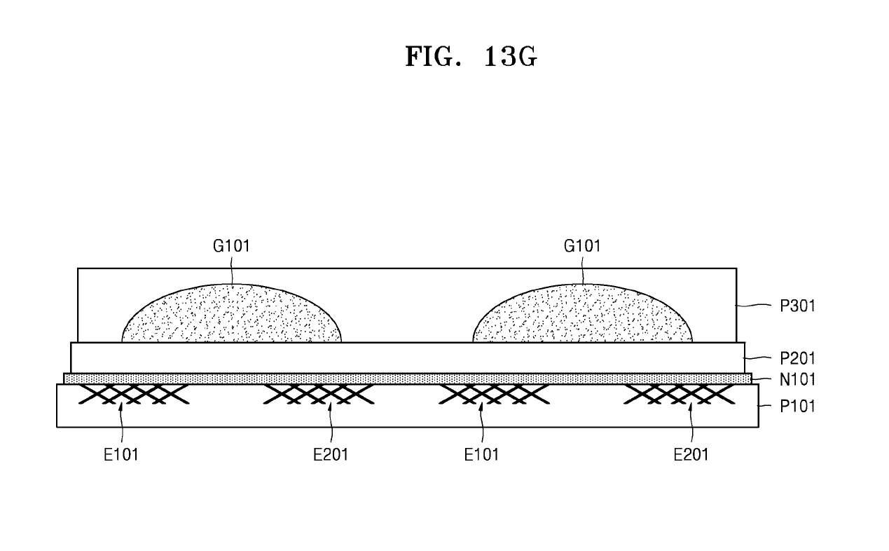

FIGS. 13A through 13G are cross-sectional views for explaining a method of manufacturing a stretchable device, according to another exemplary embodiment. The method of FIGS. 13A through 13G involves forming a plurality of stretchable devices on a single first material layer.

Referring to FIG. 13A, a plurality of first electrodes E101 and a plurality of second electrodes E201 may be formed on a substrate SUB101. The first electrodes E101 and the second electrodes E201 may be alternately arranged and may correspond to source electrodes and drain electrodes, respectively. A first material layer P101 may be formed on the substrate SUB101, covering the plurality of first electrodes E101 and the plurality of second electrodes E201. The plurality of first and second electrodes E101 and E201 may be embedded in the first material layer P101.

Referring to FIG. 13B, the first material layer P101 may be separated from the substrate SUB101 in a similar manner to that used to separate the first material layer P15 from the substrate SUB15 of FIG. 11C.

Next, the first material layer P101 may be overturned to make exposed portions of the plurality of first and second electrodes E101 and E201 face upward, as shown in FIG. 13C.

Referring to FIG. 13D, an organic semiconductor layer N101 may be formed on the first material layer P101 in which the plurality of first and second electrodes E101 and E201 are embedded, and a second material layer P201 may be formed on the organic semiconductor layer N101. A method of forming the organic semiconductor layer N101 and the second material layer P201 may be substantially the same as or similar to that described with reference to FIGS. 11E and 11F.

Referring to FIG. 13E, an elastic protective layer P30,1 having a plurality of grooves H101, may be provided. Although the grooves H101 are shown to have concave shapes in FIG. 13E, shapes of the grooves H101 may be modified in any of various other ways. The elastic protective layer P301 may include an elastomeric polymer and may be stretchable. The elastomeric polymer of the elastic protective layer P301 may be substantially the same as or similar to that of each of the first and second material layers P101 and P201.

Referring to FIG. 13F, gate electrodes G101 may be respectively formed in the plurality of grooves H101 of the elastic protective layer P301. Each of the gate electrodes G101 may be formed of, for example, a liquid metal. The liquid metal may include EGaIn. Materials and elements of the gate electrodes G101 may be modified in any of various other ways.

Referring to FIG. 13G, the elastic protective layer P301, having the plurality of grooves H101 in which the gate electrodes G101 are respectively formed, may be attached to the structure in which the organic semiconductor layer N101 and the second material layer P201 are formed on the first material layer P101 in which the plurality of first and second electrodes E101 and E201 are embedded. In this case, each of the gate electrodes G101 may be disposed in a location corresponding to a location of the second material layer P201 that is disposed between portions of the second material layer P201 beneath which two adjacent first and second electrodes E101 and E201 are disposed. The structure of FIG. 13G may correspond to the structure of FIG. 7.

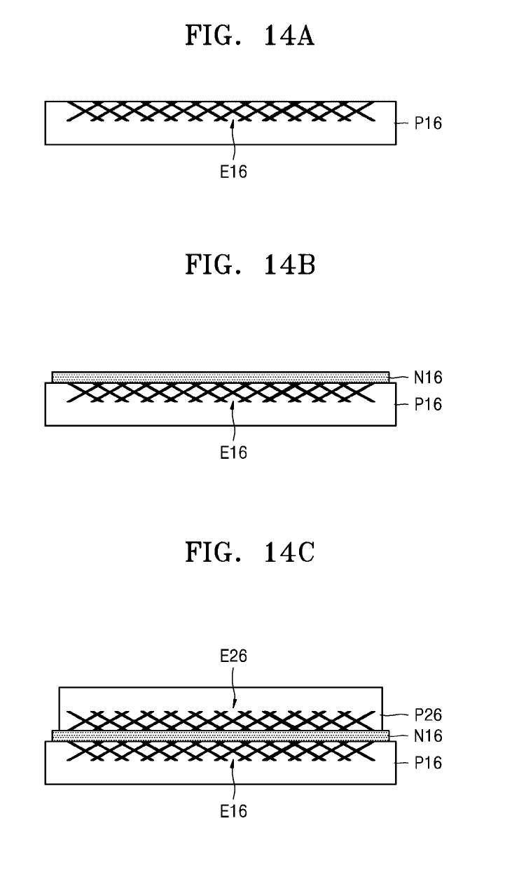

FIGS. 14A through 14C are cross-sectional views for explaining a method of manufacturing a stretchable device, according to another exemplary embodiment.

Referring to FIG. 14A, a first material layer P16 in which a first electrode E16 is embedded may be prepared. A method of forming the first material layer P16 may be similar to the method of forming the first material layer P15 in which the first and second electrodes E15 and E25 are embedded of FIG. 11D.

Referring to FIG. 14B, an organic layer N16 may be formed on the first material layer P16, wherein the organic layer N16 may include an organic semiconductor and may be electrically connected to the first electrode E16 by contacting the first electrode E16. A method of forming the organic layer N16 may be similar to the method of forming the organic semiconductor layer N15 on the first material layer P15 of FIG. 11E. For example, the organic layer N16 may be formed by using transfer printing. The organic layer N16 may include an organic semiconductor having semiconductor characteristics due to a conjugated structure. For example, the organic semiconductor may include at least one material selected from a group consisting of poly(3-hexylthiophene), TIPS-pentacene, pentacene, cyano-polyphenylene vinylene, polyacetylene, polyaniline, poly(phenylene ethynylene), poly(phenylene sulfide), poly(phenylene vinylene), polypyridine, polypyrrole, polythiophene, and polyfluorene-based polymer. The polyfluorene-based polymer may include, for example, polyfluorene, poly(fluorene vinylene), or poly(fluorenylene ethynylene).

Referring to FIG. 14C, a second material layer P26 in which a second electrode E26 is embedded, may be formed on the organic layer N16. The second electrode E26 may be electrically connected to the organic layer N16 by contacting the organic layer N16. A method of preparing the second material layer P26 in which the second electrode E26 is embedded may be substantially the same as or similar to the method of preparing the first material layer P16 in which the first electrode E16 is embedded of FIG. 14A.

The structure of FIG. 14C may correspond to the structure of FIG. 9. Accordingly, the stretchable device of FIG. 14C may be, for example, a stretchable photovoltaic device (e.g., a solar cell). The stretchable device (stretchable light-emitting device) 130 of FIG. 10 may be manufactured by using a method similar to the method of FIGS. 14A through 14C, which would be obvious to one of ordinary skill in the art based on the descriptions hereinabove and thus a detailed explanation thereof will not be given.

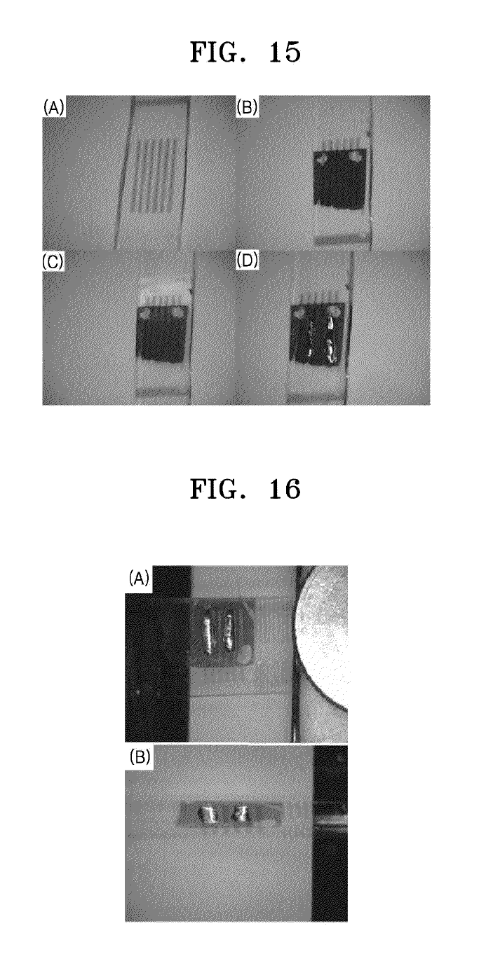

FIG. 15 shows images showing a manufacturing procedure of a stretchable device, according to an exemplary embodiment.

Part (A) of FIG. 15 shows that a plurality of electrodes (network CNT electrodes) are embedded in a first material layer (polyurethane layer) (i.e., PU layer), which may correspond to FIG. 11D. Part (B) of FIG. 15 shows that an organic semiconductor layer (P3HT layer) is formed on the first material layer (PU layer), which may correspond to FIG. 11E. Part (C) of FIG. 15 shows that a second material layer (PU layer) is formed on the organic semiconductor layer (P3HT layer), which may correspond to FIG. 11F. The second material layer (PU layer) may be transparent or almost transparent. Part (D) of FIG. 15 shows that a gate electrode (EGaIn electrode) is formed on the second material layer (PU layer), which may correspond to FIG. 11G.

FIG. 16 shows images showing an unstretched state (undeformed state) and a 150%-strained state (150%-deformed state) of a stretchable device, according to an exemplary embodiment. FIG. 16B shows that the stretchable device is deformed at 150% in a direction parallel to a direction in which current flows through a channel.

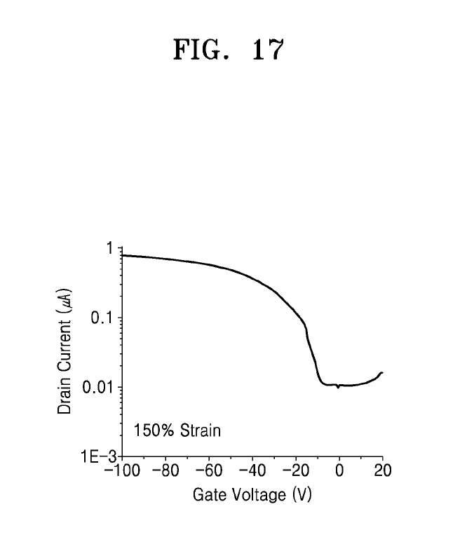

FIG. 17 is a graph illustrating a transfer curve of a device (transistor) that is tensile-strained as shown in Part (B) of FIG. 16. ON/OFF characteristics (that is, switching characteristics) of a p-type transistor are shown in FIG. 17. Accordingly, even when the device is substantially deformed, the performance of the device may be maintained.

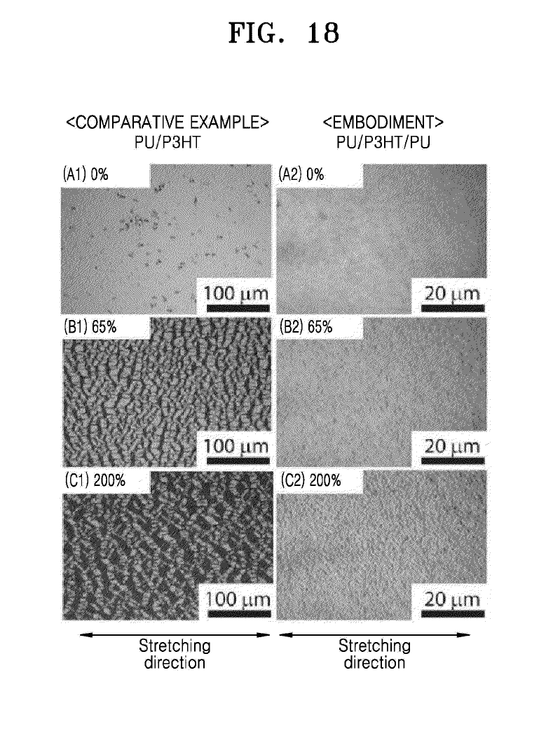

FIG. 18 shows optical microscope images illustrating a variation in morphology of an organic semiconductor layer (P3HT layer) depending on a degree of strain of a device structure (multi-layer structure), according to a comparative example and an exemplary embodiment. Images A1, B1, and C1 of FIG. 18 show results of a device structure, that is, a PU/P3HT structure, according to a comparative example, and images A2, B2, and C2 of FIG. 18 show results of a device structure, that is, a PU/P3HT/PU structure, according to an exemplary embodiment.

Referring to images A1, B1, and C1 of FIG. 18, in a structure according to the comparative example in which a P3HT layer is formed on a PU layer and a top surface of the P3HT layer is exposed, as strain increased, many cracks on a micro-scale occurred in the P3HT layer. At a strain of about 65%, cracks having widths of about 10 μm occurred throughout the entire P3HT layer, and at a strain of 200%, cracks having widths of several tens of μm (about 30 μm) occurred.

Referring to images A2, B2, and C2 of FIG. 18, in a PU/P3HT/PU structure according to an exemplary embodiment, even when strain increased, cracks having large sizes (that is, cracks on a micro-scale) hardly occurred, and very small cracks on a nano-scale occurred uniformly throughout the entire P3HT layer. At a strain of about 15-20%, no cracks occurred; at a strain of about 65%, nano-cracks having widths of tens of nm occurred; and at a strain of about 200%, nano-cracks having widths of hundreds of nm occurred. Such nano-cracks will not cut off connection of polymer chains of the P3HT layer that is an organic semiconductor layer. Accordingly, even when the device structure, that is, the PU/P3HT/PU structure, is substantially deformed (for example, even when the device structure is deformed to have a strain of 200% or more), physical properties (semiconductor characteristics) of the P3HT layer may be maintained. Accordingly, an organic semiconductor layer of a stretchable device according to one or more exemplary embodiments described herein may have mostly very fine cracks on a nano-scale at a strain of about 200%, and a ratio of micro-cracks (cracks having widths of 1 μm or more) to all cracks may be less than, for example, about 10% or 5%.

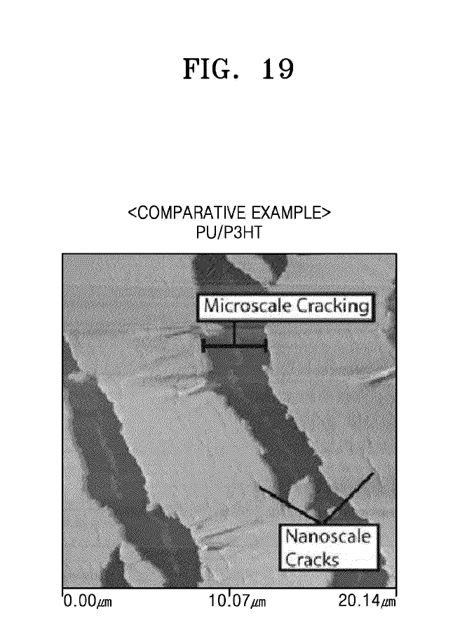

FIG. 19 is an atomic force microscope (AFM) image illustrating a state of a P3HT layer after a PU/P3HT structure according to a comparative example that is deformed to have a strain of 50%. Referring to FIG. 19, micro-cracks having widths ranging from about 3 μm to about 5 μm occurred. Also, cracks (defects) on a nano-scale occurred.

FIG. 20 is a graph illustrating a relationship between ON/OFF current and deformation of a stretchable device (transistor), according to an exemplary embodiment. FIG. 20 illustrates a result when a device is deformed in a direction parallel to a direction in which current flows through a channel and a result when the device is deformed in a direction perpendicular to the direction in which current flows through the channel. A stretchable device (transistor) that was used to obtain the results of FIG. 20 has a structure of FIG. 1, and a PU/P3HT/PU structure and a network CNT electrode are used.

Referring to FIG. 20, a reduction in ON-current as strain increased when a deformation force was applied in a direction (hereinafter, referred to as a perpendicular direction) perpendicular to a direction in which current flows through a channel was less than that when a deformation force was applied in a direction (hereinafter, referred to as a parallel direction) parallel to the direction in which current flows through the channel. This means that characteristics of a device may be more efficiently maintained when the device is deformed in the perpendicular direction than when the device is deformed in the parallel direction. Transistor characteristics (ON/OFF switching characteristics) may be maintained even at a strain of about 265% in the perpendicular direction. Meanwhile, measurements in the parallel direction were finished at a strain of about 180%, and at this point, an ON/OFF current ratio was about 10. It is found from such a result that characteristics of a transistor may be maintained at a strain of up to at least 180% in the parallel direction and may be maintained at a strain of up to at least 265% in the perpendicular direction.

FIG. 21 is a graph illustrating a relationship between a gauge factor (GF) and deformation of a stretchable device (transistor), according to an exemplary embodiment. The gauge factor (GF) refers to a ratio of a relative change in electrical resistance to mechanical strain. It may be advantageous that the stretchable device has as a small gauge factor (GF) as possible. The stretchable device (transistor) that was used to obtain the result of FIG. 21 is the same as the stretchable device of FIG. 20.

Referring to FIG. 21, when a deformation force is applied in a parallel direction, the gauge factor (GF) started at about 7, and as strain increased, the gauge factor (GF) slightly decreased and then increased. When a deformation force is applied in a perpendicular direction, the gauge factor (GF) is about 2 over the entire measurement range. Considering that a conventional stretchable graphene transistor has a gauge factor (GF) greater than 10, the stretchable device of the present embodiment may have excellent characteristics in relation to the gauge factor (GF).

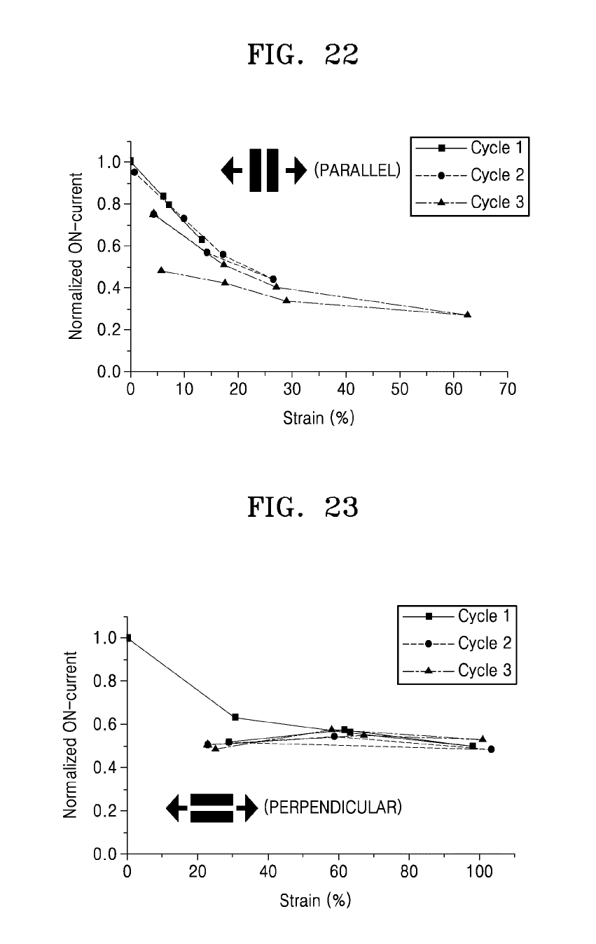

FIG. 22 is a graph illustrating a change in ON-current of a stretchable device (transistor) depending on a deformation cycle when the stretchable device is deformed (strained) in a parallel direction, according to an exemplary embodiment. FIG. 23 is a graph illustrating a change in ON-current of a stretchable device (transistor) depending on a deformation cycle when the stretchable device is deformed (strained) in a perpendicular direction, according to an exemplary embodiment. The stretchable device (transistor) that is used to obtain the results of FIGS. 22 and 23 is the same as the stretchable device of FIG. 20.

Referring to FIG. 22, when the stretchable device is deformed (strained) in the parallel direction, the stretchable device shows reversible characteristics at a relatively small strain of about 30% or less (as in Cycles 1 and 2). When strain increased to 60% or more (as in Cycle 3), there is a characteristic difference (ON-current difference) between an initial state and a restored state.

Referring to FIG. 23, when the stretchable device is deformed (strained) in the perpendicular direction, the stretchable device shows ON-current characteristics that are independent of the deformation by the repeated stretching operations. During an initial stretching operation, ON-current decreased by about 40% (as in Cycle 1), but during subsequent repeated stretching operations, the ON-current is relatively constant. Accordingly, characteristics (ON-current characteristics) of the transistor may be maintained constant even though repeated stretching operations are performed after an initial pre-stretching operation.

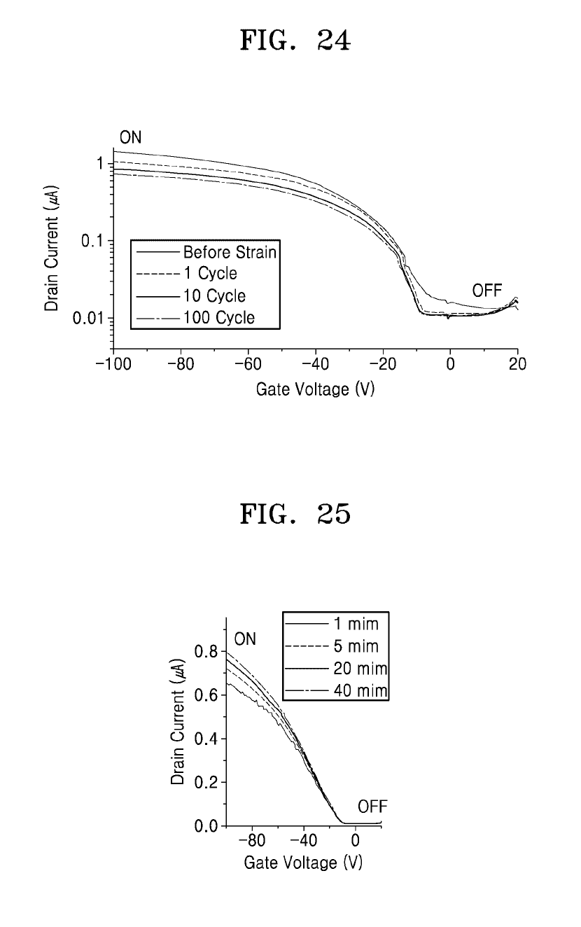

FIG. 24 is a graph illustrating a relationship between transfer characteristics and the number of stretching operations of a stretchable device, according to an exemplary embodiment. The stretchable device (transistor) that was used to obtain the result of FIG. 24 is the same as the stretchable device of FIG. 20. Transfer characteristics are evaluated while repeatedly performing an operation of pulling and releasing the stretchable device at a strain of 40% in a direction parallel to a direction in which current flows through a channel. Transfer characteristics of the stretchable device were evaluated in an unstretched state about 5 minutes later after 1, 10, and 100 stretching operations were performed.

Referring to FIG. 24, after an initial operation (that is, an initial programming operation), ON-current decreased by about 17% when 10 stretching operations (cycles) were performed and decreased by about 28% when 100 stretching operations (cycles) were performed. As the number of stretching operations increased, a decrease variation in ON-current was reduced. Meanwhile, OFF-current was maintained nearly constant even as the number of stretching operations (cycles) increased.

FIG. 25 is a graph illustrating a variation of transfer characteristics depending on the passage of time after 100 stretching operations of a stretchable device, according to an exemplary embodiment. The stretchable device (transistor) that was used to obtain a result of FIG. 25 was the same as the stretchable device of FIG. 24. Transfer characteristics according to the passage of time were evaluated after an operation of repeatedly pulling and releasing the stretchable device 100 times at a strain of 40% in a direction parallel to a direction in which current flows through a channel.

Referring to FIG. 25, when comparing a state after 1 minute elapsed and a state after 40 minutes elapsed, ON-current increased from about 0.65 μA to about 0.80 μA. Thus, a difference therebetween may be very small. Accordingly, even when a lot of time elapsed after repeated stretching operations, transfer characteristics of the stretchable device (transistor) were maintained without being greatly changed.

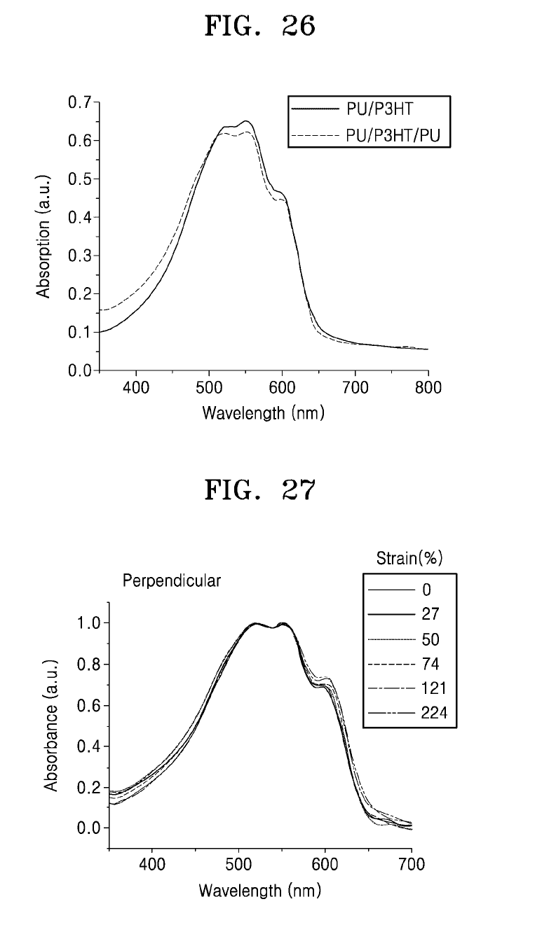

FIG. 26 is a graph illustrating light absorption characteristics of an organic semiconductor layer (P3HT layer) in a device structure (multi-layer structure), according to a comparative example and an exemplary embodiment. That is, FIG. 26 illustrates ultraviolet-visible (UV-Vis) spectra of P3HT in a PU/P3HT structure according to a comparative example and a PU/P3HT/PU structure according to an exemplary embodiment.

Referring to FIG. 26, the US-Vis spectra of P3HT in the PU/P3HT structure according to the comparative example and in the PU/P3HT/PU structure according to the exemplary embodiment are not greatly different from each other. This means that even when a PU layer is formed on a top surface of a P3HT layer, optical characteristics (light-absorption characteristics) of the P3HT layer hardly changed.

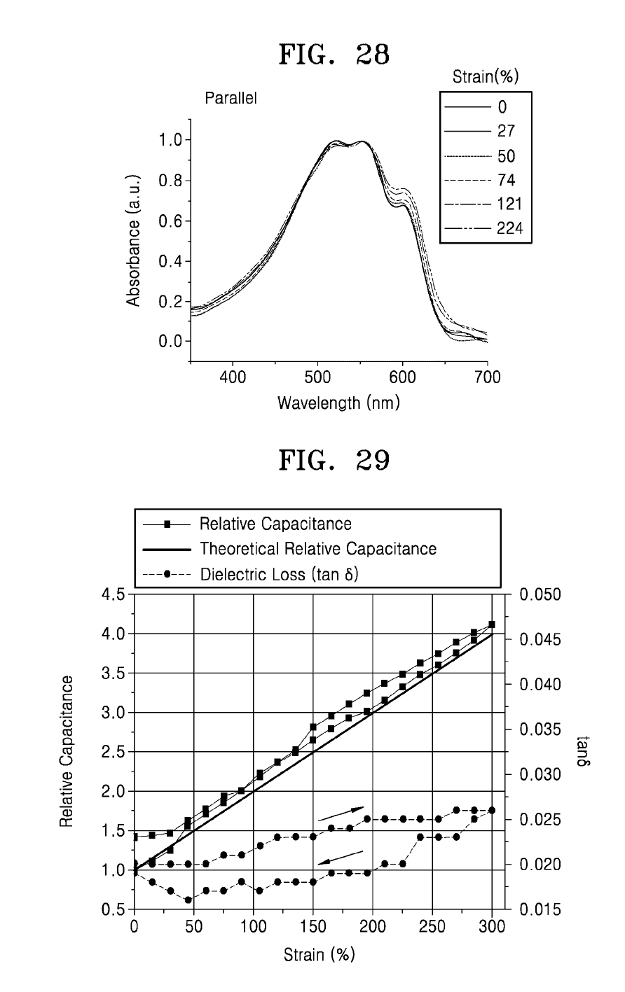

FIGS. 27 and 28 are graphs illustrating absorption spectra of a device structure (multi-layer structure) with respect to polarized incident light when the device structure is deformed (strained) in a perpendicular direction and a parallel direction, according to an exemplary embodiment. That is, FIGS. 27 and 28 illustrate absorption spectra of a PU/P3HT/PU structure with respect to polarized incident light while the PU/P3HT/PU structure is deformed in a perpendicular direction and a parallel direction.

Referring to FIGS. 27 and 28, absorption spectra are not greatly changed according to a variation of strain, but remained substantially constant. This means that even when the PU/P3HT/PU structure is deformed, optical characteristics (light-absorption characteristics) of the PU/P3HT/PU structure hardly change. Also, this may mean that even when the PU/P3HT/PU structure is deformed, a molecular packing structure of a material constituting the PU/P3HT/PU structure is substantially maintained.

FIG. 29 is a graph illustrating a relationship between properties and deformation of a PU layer that may be used in a stretchable device, according to an exemplary embodiment of the present invention. FIG. 29 shows a change in a relative capacitance and a dielectric loss (tan δ) of the PU layer according to the deformation of the PU layer. The relative capacitance and the dielectric loss were measured by deforming the PU layer to have a strain of up to 300%, and the relative capacitance and the dielectric loss were measured again by restoring the PU layer. Also, FIG. 29 illustrates a change of theoretical relative capacitance of a material having a Poisson's ratio of 0.5 according to deformation of the material. For reference, a Poisson's ratio of the PU layer may be 0.5.

Referring to FIG. 29, a change in a relative capacitance of the PU layer according to the deformation thereof is similar to that of the theoretical relative capacitance. Meanwhile, a dielectric loss (tan δ) slightly increases as strain increases.

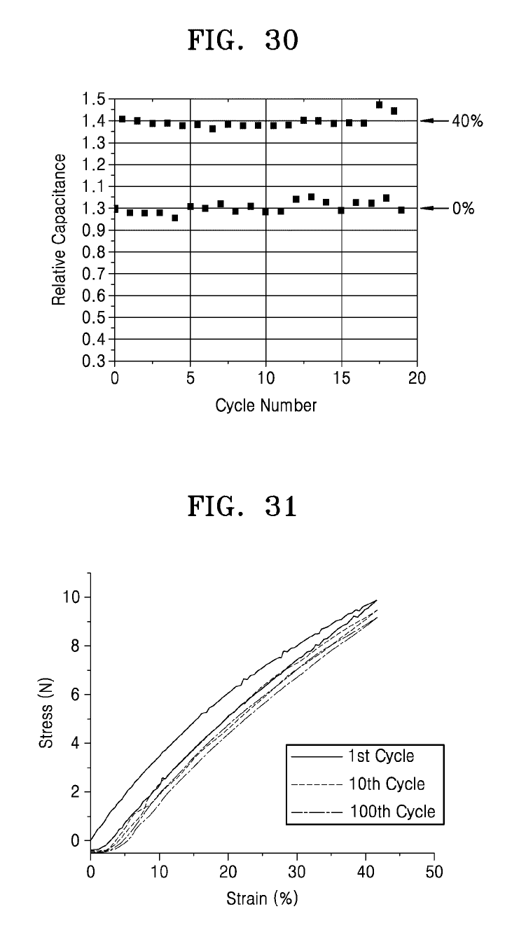

FIG. 30 is a graph illustrating a relationship between properties and a deformation cycle number of a PU layer that may be used in a stretchable device, according to an exemplary embodiment. FIG. 30 illustrates a relationship between a relative capacitance and a deformation cycle number of a PU layer. A relative capacitance was measured by repeatedly deforming and then restoring a PU layer to have a strain of up to 40%.

Referring to FIG. 30, even when a deformation cycle number increased, a relative capacitance of a PU layer remained substantially constant. This means that even when a deformation cycle number increases, the stability of a stretchable device is ensured.

FIG. 31 is a graph illustrating stress-strain characteristics of a PU layer that may be used in a stretchable device, according to an exemplary embodiment. Stress-strain characteristics were measured when the PU layer was deformed a 1st time, a 10th time, and a 100th time at a strain of 40%.

Referring to FIG. 31, although there is a behavior difference between when the PU layer is pulled and when the PU layer is released in a first cycle, the behavior difference is greatly reduced as the number of deformation cycles increases. There is a small behavior difference between when the PU layer is pulled and when the PU layer is released in a 10th cycle and in a 100th cycle. Also, viscous deformation characteristics of the PU layer increase as the deformation cycle number increases.

As described above, according to the one or more exemplary embodiments, a stretchable device having excellent characteristics may be obtained. The stretchable device may have a high strain of 250% or more and may maintain excellent performance even when a lot of time has elapsed after repeated stretching operations. In other words, the stretchable device may have excellent stability and reliability. Also, since the stretchable device has a relatively simple structure, the stretchable device may be easily manufactured. The stretchable device may be used in devices in any of various fields such as a photovoltaic device (e.g., a solar cell), a light-emitting device, and a sensor as well as a transistor. Also, the stretchable device may be used with electronic skins and skin sensors for robotic apparatuses, wearable electronic apparatuses, bio-integrated devices, and stretchable display devices.

In addition, when the organic layer (or the organic semiconductor layer) N10 (see FIG. 1) that is disposed between the first and second material layers P10 and P20 (see FIG. 1) is formed of a polymer material that is stretchable, such as elastomeric rubber, even though the stretchable device is deformed at a strain equal to or greater than a strain limit at which the polymer material itself may be stretched, the stretchable device may continue to operate normally. The stretchable device may have a very high strain of, for example, about 300% or more.

It should be understood that the exemplary embodiments described herein should be considered in a descriptive sense only and not for purposes of limitation. For example, it will be understood by one of ordinary skill in the art that the stretchable device of any of FIGS. 1 through 10 may be configured in any of various other ways. In detail, at least one electrode element may be embedded in the organic layer (the organic semiconductor layer) (e.g., N10 of FIG. 1) instead of in the first or second material layer (e.g., P10 or P20 of FIG. 1). Also, the method of manufacturing a stretchable device described with reference to any of FIGS. 11A through 11G, 12A through 12E, 13A through 13G, and 14A through 14C may be modified in any of various other ways. The stretchable devices according to the one or more exemplary embodiments may be applied to various fields other than a transistor, a photovoltaic device, a light-emitting device, a sensor, and a display device. Accordingly, the scope of the invention is defined not by the detailed description but by the appended claims.

What is claimed is:

1. A stretchable device comprising:
a first material layer comprising a first stretchable elastomeric polymer;
a second material layer comprising a second stretchable elastomeric polymer;
an organic layer, disposed between the first and second material layers, and comprising an organic semiconductor; and
at least one electrode element embedded in at least one of the first material layer and the second material layer, wherein the at least one electrode element contacts the organic layer,
wherein the stretchable device is stretchable in a direction parallel to the organic layer.

2. The stretchable device of claim 1, wherein the first stretchable elastomeric polymer and the second stretchable elastomeric polymer each have a Poisson's ratio of at least 0.4.

3. The stretchable device of claim 1, wherein at least one of the first stretchable elastomeric polymer and the second stretchable elastomeric polymer comprises at least one material selected from a group consisting of polyurethane, polyurethane acrylate, acrylate polymer, acrylate terpolymer, and silicone-based polymer,
wherein the silicone-based polymer comprises at least one material selected from a group consisting of polydimethylsiloxane, polyphenylmethylsiloxane, and hexamethyldisiloxane.

4. The stretchable device of claim 1, wherein the organic semiconductor comprises an organic material having a conjugated structure.

5. The stretchable device of claim 4, wherein the organic semiconductor comprises at least one material selected from a group consisting of poly(3-hexylthiophene), TIPS-pentacene, pentacene, cyano-polyphenylene vinylene, polyacetylene, polyaniline, poly(phenylene ethynylene), poly(phenylene sulfide), poly(phenylene vinylene), polypyridine, polypyrrole, polythiophene, and polyfluorene-based polymer.

6. The stretchable device of claim 1, wherein the at least one electrode element has a network structure.

7. The stretchable device of claim 1, wherein the at least one electrode element comprises at least one material selected from a group consisting of carbon nanotubes, metal nanowires, and graphene.

8. The stretchable device of claim 1, wherein the at least one electrode element comprises a first electrode and a second electrode, and
wherein the first electrode and the second electrode are separate from each other.

9. The stretchable device of claim 1, wherein the at least one electrode element comprises a first electrode that is embedded in the first material layer, and a second electrode that is embedded in the second material layer.

10. The stretchable device of claim 1, wherein the stretchable device is a transistor,
wherein the at least one electrode element comprises a source electrode and a drain electrode, and
wherein the stretchable device further comprises a gate electrode configured to apply an electric field to the organic layer.

11. The stretchable device of claim 10, wherein the gate electrode comprises at least one material selected from a group consisting of a liquid metal, carbon nanotubes, metal nanowires, and graphene.

12. The stretchable device of claim 10, further comprising an elastic protective layer that covers the gate electrode.

13. The stretchable device of claim 1, wherein the stretchable device is a photovoltaic device,
wherein at least one electrode element comprises a first electrode that is embedded in a side of the first material layer adjacent to the organic layer and a second electrode that is embedded in a side of the second material layer adjacent to the organic layer.

14. The stretchable device of claim 1, wherein the stretchable device is a light-emitting device,
wherein the at least one electrode element comprises a first electrode that is embedded in a side of the first material layer adjacent to the organic layer and a second electrode that is embedded in a side of the second material layer adjacent to the organic layer.

15. The stretchable device of claim 1, wherein the stretchable device is under a strain of at least 10%.

16. The stretchable device of claim 1, wherein semiconductor characteristics of the stretchable device under no strain are substantially the same as semiconductor characteristics of the stretchable device under a strain of at least 150% due to a presence of nano-cracks in the organic layer.

17. A stretchable transistor comprising:
a first elastomeric polymer layer that has a Poisson's ratio of at least 0.4;
a second elastomeric polymer layer that has a Poisson's ratio of at least 0.4;
an organic semiconductor layer disposed between the first elastomeric polymer layer and the second elastomeric polymer layer;
a source electrode embedded in one of the first elastomeric polymer layer and the second elastomeric polymer layer and electrically connected to the organic semiconductor layer;
a drain electrode embedded in one of the first elastomeric polymer layer and the second elastomeric polymer layer and electrically connected to the organic semiconductor layer; and
a gate electrode disposed on one of the first elastomeric polymer layer and the second elastomeric polymer layer.

18. The stretchable transistor of claim 17, wherein each of the source electrode and the drain electrode comprises a network carbon nanotube structure.

19. The stretchable transistor of claim 17, wherein the gate electrode comprises a liquid metal.

20. A method of manufacturing a stretchable device, the method comprising:
preparing a first material layer comprising a stretchable elastomeric polymer;
forming an organic layer on the first material layer, the organic layer comprising an organic semiconductor; and
forming a second material layer on the organic layer, the second material layer comprising a stretchable elastomeric polymer,
wherein the preparing the first material layer and the forming the second material layer further comprise forming at least one electrode element therein that contacts the organic layer.

21. The method of claim 20, wherein the preparing of the first material layer comprises:
forming the at least one electrode element on a substrate;
forming a material layer on the substrate, such that the at least one electrode element is embedded in the material layer; and
separating the material layer and the at least one electrode embedded therein from the substrate.

22. The method of claim 20, wherein the forming the organic layer comprises using transfer printing.

23. The method of claim 20, wherein the at least one electrode element comprises at least one material selected from a group consisting of carbon nanotubes, metal nanowires, and graphene.

24. The method of claim 20, wherein the at least one electrode element comprises a first electrode and a second electrode spaced apart from the first electrode.

25. The method of claim 20, wherein the stretchable device is a transistor, and the at least one electrode element comprises a source electrode and a drain electrode, and
wherein the method further comprises forming a gate electrode.

26. The method of claim 25, further comprising forming an elastic protective layer that covers the gate electrode.

27. The method of claim 20, wherein the stretchable device is one of a photovoltaic device, a light-emitting device, and a sensor.

28. A stretchable device comprising:
a first stretchable material layer comprising a first elastomeric polymer which is stretchable in at least a first direction and has a Poisson's ratio of at least 0.4;
a second stretchable material layer comprising a second elastomeric polymer which is stretchable in at least the first direction and has a Poisson's ratio of at least 0.4;
an organic layer, comprising an organic semiconductor, disposed between the first stretchable material layer and the second stretchable material layer; and
at least one electrode, contacting the organic layer and embedded in at least one of the first stretchable material layer and the second stretchable material layer;
wherein the first direction is substantially parallel to a plane of the organic layer.
